(19) United States
(12) Patent Application Publication
(10) Pub. No.: US 2026/0305154 A1
(43) Pub. Date: Oct. 1, 2026

(54) IONOELASTOMER MATERIAL WITH IMPROVED ION MOBILITY, DIODE DEVICE INCLUDING THE SAME, LOGIC GATE CONTROLLED BY LIGHT USING THE SAME, AND DEVICE CONTROLLED BY LIGHT INCLUDING THE SAME

(71) Applicant: UIF (University Industry Foundation), Yonsei University, Seoul (KR)

(72) Inventors: Cheol Min PARK, Seoul (KR); Yeon Ji KIM, Seoul (KR); Seung Won LEE, Seoul (KR); Ji Hye JANG, Danyang-gun (KR)

(73) Assignee: UIF (University Industry Foundation), Yonsei University, Seoul (KR)

(21) Appl. No.: 19/438,246

(22) Filed: Dec. 31, 2025

(30) Foreign Application Priority Data
Feb. 24, 2025 (KR) 10-2025-0023456

(51) Int. Cl. H10K 85/10; H10K 30/20; H10K 30/60; H10K 30/85; H10K 30/86

(52) U.S. Cl. CPC H10K 85/113; H10K 30/20; H10K 30/60; H10K 30/85; H10K 30/86

(57) ABSTRACT

Disclosed are a composite ionoelastomer material having enhanced ionic mobility, a diode device including the same, a light-responsive gate whose characteristics are adjustable by light using the diode device, and a light-controlled device including the gate. The composite ionoelastomer material may include an ionoelastomer and a positively charged or negatively charged MXene included in the ionoelastomer and interacting with one of a cation and an anion contained in the ionoelastomer.

### CROSS-REFERENCE TO RELATED APPLICATION

This application claims priority from Korean Patent Application No. 10-2025-0023456, filed on Feb. 24, 2025 in the Korean Intellectual Property Office, and all the benefits accruing therefrom under 35 U.S.C. 119. The contents of each of the above applications are incorporated herein in their entirety by reference.

### BACKGROUND

### Field

The present invention relates to a composite ionoelastomer material having enhanced ionic mobility, a diode device including the same, a light-responsive logic gate whose characteristics are adjustable by light using the diode device, and a light-controlled device including the same.

### Description of Related Art

An ionic junction may be established by physically stacking an ionic conductor having preferential transport of cations (p-type) with another ionic conductor having preferential transport of anions (n-type). As a result, an ionic rectification behavior analogous to that of an electronic p-n junction may be obtained. Ionic current rectification and switching have been demonstrated in various gel-based materials, including aqueous polyelectrolytes comprising positive or negative ions within polymer networks, hydrogels containing dissolved salts, organohydrogels, bipolar membranes, charged nanochannels, and materials involving metal-electrolyte redox reactions. Accordingly, such ionic junctions may be applicable to sensors, soft power generators, and ionic logic circuits. However, most previously reported ionic devices suffer from solvent leakage and evaporation, which may cause inevitable degradation of device performance.

Recently, elastomeric liquid-free ionic conductors, also referred to as ionoelastomers, have attracted attention due to their solvent-free characteristics and superior environmental stability. Ionoelastomers based on polyelectrolytes may exhibit excellent mechanical properties with minimal solvent and ion leakage, in addition to selective ion transport characteristics, thereby enabling various solid-state ionic junction devices exhibiting notable ionic current rectification.

In order to expand the applicability of solid-state ionic junction devices, there is a demand for the development of ionoelastomer junctions in which ionic current rectification is reversibly responsive to external stimuli such as mechanical pressure, temperature, light, and humidity, thereby making such junctions suitable for sensory ionic junction applications. For this purpose, materials may be carefully designed by incorporating stimuli-responsive fillers into an ionoelastomer to form a stimuli-responsive ionic junction with enhanced rectification performance. Two-dimensional nanosheets of MXenes (Ti₃C₂Tₓ; transition metal carbides or carbonitrides) have attracted significant interest due to their high electrical conductivity, large specific surface area with abundant hydrophilic surface functional groups, and excellent photothermal conversion properties, which enable applications such as sensors, energy storage or harvesting devices, electromagnetic interference shielding components, and biomedicines. Hydrophilic MXene nanosheets may be incorporated into an ionoelastomer, and further, the photothermal properties of MXene may enable the formation of an ionoelastomer junction exhibiting a near-infrared response when the ionic rectification of the junction is temperature sensitive.

### SUMMARY

An NIR-responsive ionic junction enabling a switchable logic gate is provided. A bilayer ionic junction, in which a p-type ionoelastomer containing MXene nanosheets having a positive surface potential is stacked on an n-type ionoelastomer containing MXene nanosheets having a negative surface potential, is disposed between two intrinsically stretchable liquid metal electrodes, thereby forming an NIR-responsive ionic junction device. Current rectification of the device may be further enhanced upon exposure to NIR radiation due to an increase in device temperature, which may be attributed to NIR-to-thermal energy conversion by the MXene nanosheets. By controlling the rectification ratio of the ionic junction through adjustment of NIR exposure time and NIR power, a switchable ionic logic gate may be realized, in which a logic transition from an AND operation to an OR operation occurs reversibly through NIR exposure and subsequent device cooling processes applied to two ionic junctions connected in series.

The problem to be solved by the present invention is to overcome solvent leakage and environmental instability associated with conventional ionic conductors and to develop a material having higher ionic mobility. To this end, the present invention proposes forming a composite ionoelastomer material by mixing an ionoelastomer with a charged MXene, and further proposes a diode device and a light-controlled device using the composite ionoelastomer material. Such an approach may contribute to enhancement of ionic conductivity, improvement of stability, and modulation of characteristics of a logic gate using light.

In one aspect, the present invention provides a composite ionoelastomer material having enhanced ionic mobility, comprising an ionoelastomer and a positively charged or negatively charged MXene included in the ionoelastomer and interacting with one of a cation and an anion contained in the ionoelastomer.

In one embodiment, mobility of ions having the same charge as the MXene included in the ionoelastomer may be enhanced.

In one embodiment, the ionoelastomer may comprise one or more materials selected from the group consisting of 1-ethyl-3-methylimidazolium (3-sulfopropyl) acrylate ([EMIM][SPA]) and 1-[2-acryloyloxyethyl]-3-butylimidazolium bis(trifluoromethane)sulfonimide ([AEBI][TFSI]).

In one embodiment, the MXene may comprise one or more materials selected from the group consisting of Ti₃C₂Tₓ and Ti₃C₂Tₓ surface-treated with polyethyleneimine.

In another aspect, the present invention provides an ionoelastomer-based diode device having enhanced ionic mobility, comprising an n-side portion including an ionoelastomer and a negatively charged MXene interacting with cations contained in the ionoelastomer, and a p-side portion including an ionoelastomer and a positively charged MXene interacting with anions contained in the ionoelastomer, wherein the p-side portion is in contact with the n-side portion.

In one embodiment, the diode device may further comprise a first electrode in contact with the n-side portion, and a second electrode spaced apart from the first electrode and in contact with the p-side portion.

In one embodiment, the ionoelastomer of the n-side portion may comprise one or more materials selected from the group consisting of 1-[2-acryloyloxyethyl]-3-butylimidazolium bis(trifluoromethane)sulfonimide ([AEBI][TFSI]).

In one embodiment, the ionoelastomer of the p-side portion may comprise one or more materials selected from the group consisting of 1-ethyl-3-methylimidazolium (3-sulfopropyl) acrylate ([EMIM][SPA]).

In one embodiment, the MXene included in the n-side portion may comprise one or more materials selected from the group consisting of Ti₃C₂Tₓ.

In one embodiment, the MXene included in the p-side portion may comprise one or more materials selected from the group consisting of Ti₃C₂Tₓ surface-treated with polyethyleneimine.

In one embodiment, the MXene included in the n-side portion or the p-side portion may be present in an amount of about 0.5 to 3 wt %.

In another aspect, the present invention provides a light-responsive logic gate comprising a diode device including an n-side portion including an ionoelastomer and a negatively charged MXene interacting with cations contained in the ionoelastomer, and a p-side portion including an ionoelastomer and a positively charged MXene interacting with anions contained in the ionoelastomer, wherein the p-side portion is in contact with the n-side portion, two input electrodes in contact with the p-side portion, and an output electrode spaced apart from the input electrodes and in contact with the n-side portion, wherein characteristics of the logic gate are adjustable by light.

In one embodiment, the diode device may comprise the ionoelastomer-based diode device having enhanced ionic mobility according to the embodiments of the present invention described above.

In one embodiment, upon irradiation with light, an electrical resistance of the diode device may decrease.

In another aspect, the present invention provides a light-controlled device comprising a light-responsive gate and a light source configured to irradiate light onto the gate.

In one embodiment, the gate may comprise the gate according to the embodiments of the present invention described above.

The effects of the present invention include enhancement of ionic conductivity, thereby improving performance of a diode device. As a result, more efficient electronic device design may be achieved, and applicability in various fields may be expanded. In particular, in the case of a light-controlled device, characteristics may be adjusted by external light, thereby providing greater flexibility compared to conventional devices having fixed characteristics. This may lead to innovative technological advancement in development of next-generation electronic devices and wearable devices, and may further contribute to realization of high-performance devices capable of stable operation in various environments.

### BRIEF DESCRIPTION OF DRAWINGS

FIG. 1A. Schematic illustrations of an n-type ionoelastomer (AT) and a p-type ionoelastomer(ES), schematic representations of negatively charged MXene (NMXene) and positively charged MXene (PMXene) showing surface functional groups with negative and positive dipoles, respectively, and formation of AT-NMXene and ES-PMXene composites by mixing ionoelastomers with charged MXenes.

FIG. 1B. Scanning electron microscopy images of NMXene and PMXene on anodized aluminum oxide membranes and transmission electron microscopy images of NMXene and PMXene showing two-dimensional sheet structures.

FIG. 1C. X-ray photoelectron spectroscopy spectra of NMXene and PMXene.

FIG. 1D. Zeta potential measurements of NMXene and PMXene.

FIG. 1E. X-ray diffraction patterns of NMXene and PMXene.

FIG. 1F. Photographs of AT-NMXene and ES-PMXene ionoelastomer composites.

FIG. 1G. X-ray diffraction patterns of AT, AT-NMXene, ES, and ES-PMXene.

FIG. 1H. Differential scanning calorimetry thermograms of AT, AT-NMXene, ES, and ES-PMXene.

FIG. 1I. Stress-strain curves of AT, AT-NMXene, ES, and ES-PMXene with different MXene contents.

FIG. 2A. Nyquist plots of AT-NMXene homojunctions with different NMXene contents.

FIG. 2B. Nyquist plots of ES-PMXene homojunctions with different PMXene contents.

FIG. 2C. Ionic conductivity of AT-NMXene as a function of NMXene content.

FIG. 2D. Ionic conductivity of ES-PMXene as a function of PMXene content.

FIG. 2E. Diffusion coefficients of [TFSI]⁻ anions in AT and AT-NMXene obtained by diffusion ordered spectroscopy.

FIG. 2F. Diffusion coefficients of [EMIM]⁺ cations in ES and ES-PMXene obtained by diffusion ordered spectroscopy.

FIG. 2G. Schematic illustration of AT-NMXene showing enhanced effective mobile anions.

FIG. 2H. Schematic illustration of ES-PMXene showing enhanced effective mobile cations.

FIG. 3A. Schematic illustration of an ES-PMXene/AT-NMXene heterojunction diode.

FIG. 3B. Schematic illustration of the operating mechanism of the ES-PMXene/AT-NMXene junction diode under forward bias and reverse bias.

FIG. 3C. Nyquist plots obtained from AC-impedance measurements of an ES-PMXene/AT-NMXene junction containing 1 wt % MXene under different direct current biases.

FIG. 3D. Bode phase plots obtained from AC-impedance measurements of an ES-PMXene/AT-NMXene junction containing 1 wt % MXene under different direct current biases.

FIG. 3E. Current density responses of an ES-PMXene/AT-NMXene junction under various forward and reverse bias conditions.

FIG. 3F. Nyquist plots of ES-PMXene/AT-NMXene heterojunctions containing 0, 0.5, 1, and 3 wt % MXene.

FIG. 3G. Impedance spectra of ES-PMXene/AT-NMXene heterojunctions containing 0, 0.5, 1, and 3 wt % MXene as a function of frequency.

FIG. 3H. Capacitance-frequency characteristics of ES-PMXene/AT-NMXene heterojunctions containing 0, 0.5, 1, and 3 wt % MXene.

FIG. 3I. Current density responses of ES-PMXene/AT-NMXene heterojunctions with different MXene contents under forward and reverse bias conditions.

FIG. 3J. Rectification ratios of ES-PMXene/AT-NMXene heterojunction diodes measured at +0.4 V and −0.4 V as a function of MXene content.

FIG. 3K. Charge density versus voltage characteristics of ES-PMXene/AT-NMXene heterojunction diodes with different MXene contents.

FIG. 4A. Schematic illustration of an NIR-responsive ES-PMXene/AT-NMXene heterojunction diode based on the photothermal effect of MXene and infrared thermographic images showing time-dependent temperature variation of the junction under NIR irradiation at a power density of 400 mW cm⁻².

FIG. 4B. Ultraviolet-visible-near-infrared absorption spectra of ES, ES-PMXene, AT, and AT-NMXene.

FIG. 4C. Time-dependent temperature profiles of an ES-PMXene/AT-NMXene junction as a function of NIR power density.

FIG. 4D. Temperature variation of an ES-PMXene/AT-NMXene junction diode under repeated NIR ON and OFF irradiation cycles.

FIG. 4E. Nyquist plots of an ES-PMXene/AT-NMXene junction diode measured as a function of NIR power density.

FIG. 4F. Relative rectification ratios of an ES-PMXene/AT-NMXene junction diode as a function of NIR power density.

FIG. 4G. Charge density versus voltage characteristics of an ES-PMXene/AT-NMXene junction diode measured with and without NIR irradiation.

FIG. 5A. Schematic illustration of an ionic logic gate composed of two ES-PMXene/AT-NMXene junction diodes and a series-connected resistor, including corresponding circuit configurations.

FIG. 5B. Schematic illustration of a switchable ionic logic gate employing NIR-responsive junction diodes, showing reversible transition between AND logic operation and OR logic operation under NIR heating and cooling.

FIG. 5C. Output current profiles of the ionic logic gate corresponding to AND logic operation, OR logic operation under NIR exposure, and recovery to AND logic operation after NIR turn-off.

FIG. 5D. Time-dependent variations in output current of the ionic logic gate during repeated cycles of NIR irradiation and cooling.

FIG. 5E. Time-dependent variations in output voltage of the ionic logic gate with a series resistor during repeated cycles of NIR irradiation and cooling.

FIG. 5F. Schematic illustration of an NIR-responsive ionic logic gate integrated with a light-emitting diode indicator system and a circuit configuration including an Arduino controller.

FIG. 5G. Photographs showing light-emitting diode ON and OFF states corresponding to OR logic and AND logic operations, respectively, controlled by NIR irradiation and subsequent cooling.

FIG. 6. Schematic illustration of synthesis of positively charged MXene by surface functionalization of MXene with branched polyethyleneimine.

FIG. 7. Schematic illustration of synthesis of ES-PMXene and AT-NMXene ionoelastomer composites.

FIG. 8. (LEFT) X-ray photoelectron spectroscopy C 1s and Ti 2p spectra of pristine MXene. (MIDDLE) X-ray photoelectron spectroscopy C 1s and Ti 2p spectra of carboxylic-acid-functionalized MXene. (RIGHT) X-ray photoelectron spectroscopy C 1s and Ti 2p spectra of branched polyethyleneimine-functionalized MXene.

FIG. 9A. Transmission electron microscopy image and energy-dispersive spectroscopy elemental mapping images of NMXene showing distributions of Ti, O, N, and F.

FIG. 9B. Transmission electron microscopy image and energy-dispersive spectroscopy elemental mapping images of PMXene showing distributions of Ti, O, N, and F.

FIG. 10. Fourier transform infrared spectroscopy spectra of MXene, MXene-COOH, and MXene-BPEI showing characteristic absorption peaks associated with OH, C O, N H, O H, C N, and C F bonding vibrations.

FIG. 11. Raman spectra of MXene, MXene-COOH, and MXene-BPEI showing lattice skeleton vibrations, vibrations of outermost atoms, and phonon modes of carbon atoms.

FIG. 12. Thermogravimetric analysis profiles of AT, AT-NMXene, ES, and ES-PMXene measured at a heating rate of 10 °C min⁻¹.

FIG. 13. Attenuated total reflectance Fourier-transform infrared spectroscopy spectra of AT, AT-NMXene containing 1 wt % MXene, ES, and ES-PMXene containing 1 wt % MXene, showing characteristic absorbance bands corresponding to C C symmetric stretching, C C asymmetric stretching, and C CH2 twisting modes, and water vibration bands in ES-based samples.

FIG. 14A. Nyquist plots of AT and AT mixed with 1 wt % PMXene.

FIG. 14B. Nyquist plots of ES and ES mixed with 1 wt % NMXene, showing slight increases in bulk resistance.

FIG. 15A. Self-diffusion coefficients of mobile [TFSI]⁻ anions in AT, AT-NMXene, and AT-PMXene.

FIG. 15B. Self-diffusion coefficients of mobile [EMIM]⁺ cations in ES, ES-PMXene, and ES-NMXene.

FIG. 16A. Capacitance-frequency characteristics of AT/AT and AT-NMXene/AT-NMXene junctions containing 1 wt % MXene.

FIG. 16B. Capacitance-frequency characteristics of ES/ES and ES-PMXene/ES-PMXene junctions containing 1 wt % MXene, showing increased electric double layer capacitance in low-frequency regions.

FIG. 17A. X-ray photoelectron spectroscopy N 1s spectrum of AT.

FIG. 17B. X-ray photoelectron spectroscopy N 1s spectrum of AT-NMXene containing 1 wt % MXene.

FIG. 17C. X-ray photoelectron spectroscopy N 1s spectrum of ES.

FIG. 17D. X-ray photoelectron spectroscopy N 1s spectrum of ES-PMXene containing 1 wt % MXene.

FIG. 18A. Real impedance versus frequency curves of ES-PMXene/AT-NMXene heterojunctions containing 1 wt % MXene under forward and reverse bias conditions.

FIG. 18B. Imaginary impedance versus frequency curves of ES-PMXene/AT-NMXene heterojunctions containing 1 wt % MXene under forward and reverse bias conditions.

FIG. 19A. Current density responses of AT-NMXene/AT-NMXene homojunctions under forward and reverse bias conditions.

FIG. 19B. Current density responses of ES-PMXene/ES-PMXene homojunctions under forward and reverse bias conditions.

FIG. 20. Current density stability of an ES-PMXene/AT-NMXene heterojunction containing 1 wt % MXene during 100 cycles of repeated forward and reverse bias application.

FIG. 21A. Schematic illustration of an ES-PMXene/AT-NMXene junction under applied mechanical strain.

FIG. 21B. Nyquist plots of an ES-PMXene/AT-NMXene junction containing 1 wt % MXene at different stretching ratios.

FIG. 22. Temperature variation of a pure ES/AT junction diode under near-infrared irradiation at a power density of 400 mW cm⁻², showing negligible temperature change.

FIG. 23. Temperature variation of a photothermally heated ES-PMXene/AT-NMXene junction diode containing 1 wt % MXene during repeated ON and OFF cycles of near-infrared irradiation.

FIG. 24. Temperature-dependent Nyquist plots of an ES-PMXene/AT-NMXene junction diode containing 1 wt % MXene, showing a decrease in bulk resistance with increasing temperature.

FIG. 25A. Bode plots of ES/AT and ES-PMXene/AT-NMXene junctions at 23 °C.

FIG. 25B. Bode plots of ES/AT and ES-PMXene/AT-NMXene junctions at 30 °C.

FIG. 25C. Bode plots of ES/AT and ES-PMXene/AT-NMXene junctions at 40 °C.

FIG. 25D. Bode plots of ES/AT and ES-PMXene/AT-NMXene junctions at 50 °C.

FIG. 25E. Bode plots of ES/AT and ES-PMXene/AT-NMXene junctions at 60 °C.

FIG. 25F. Bode plots of ES/AT and ES-PMXene/AT-NMXene junctions at 70 °C.

FIG. 25G. Charge relaxation frequency as a function of temperature for ES/AT and ES-PMXene/AT-NMXene junctions.

FIG. 25H. Charge relaxation time as a function of temperature for ES/AT and ES-PMXene/AT-NMXene junctions.

FIG. 26A. Capacitance-frequency curves of ES/AT and ES-PMXene/AT-NMXene junctions at 23 °C.

FIG. 26B. Capacitance-frequency curves of ES/AT and ES-PMXene/AT-NMXene junctions at 30 °C.

FIG. 26C. Capacitance-frequency curves of ES/AT and ES-PMXene/AT-NMXene junctions at 40 °C.

FIG. 26D. Capacitance-frequency curves of ES/AT and ES-PMXene/AT-NMXene junctions at 50 °C.

FIG. 26E. Capacitance-frequency curves of ES/AT and ES-PMXene/AT-NMXene junctions at 60 °C.

FIG. 26F. Capacitance-frequency curves of ES/AT and ES-PMXene/AT-NMXene junctions at 70 °C.

FIG. 26G. Capacitance values of ionoelastomer bilayers as a function of temperature.

FIG. 27. Ratio of capacitance values defined as (C_{for}−C_{eq})/(C_{eq}−Cᵣₑᵥ) as a function of temperature.

FIG. 28A. Current density responses of an ES-PMXene/AT-NMXene junction containing 1 wt % MXene at 23 °C.

FIG. 28B. Current density responses of an ES-PMXene/AT-NMXene junction containing 1 wt % MXene at 30 °C.

FIG. 28C. Current density responses of an ES-PMXene/AT-NMXene junction containing 1 wt % MXene at 40 °C.

FIG. 28D. Current density responses of an ES-PMXene/AT-NMXene junction containing 1 wt % MXene at 50 °C.

FIG. 28E. Current density responses of an ES-PMXene/AT-NMXene junction containing 1 wt % MXene at 60 °C.

FIG. 28F. Current density responses of an ES-PMXene/AT-NMXene junction containing 1 wt % MXene at 70 °C.

FIG. 28G. Charge density values of ES-PMXene/AT-NMXene junctions as a function of temperature.

FIG. 28H. Rectification ratios of ES-PMXene/AT-NMXene junctions as a function of temperature.

FIG. 29. Schematic illustrations and photographs of a switchable ionic logic gate including a stencil-printed liquid metal electrode circuit.

FIG. 30. Square-wave voltage input signals applied to input terminals A and B at frequencies of 0.025 Hz and 0.05 Hz, respectively.

FIG. 31. Output current variations of a switchable ionic logic gate including an ES-PMXene/AT-NMXene junction during progression of four logic input states of (1,1), (1,0), (0,1), and (0,0) under near-infrared irradiation.

FIG. 32. (LEFT) Output voltage profile of a switchable ionic logic gate operating in an AND logic state. (MIDDLE) Output voltage profile of a switchable ionic logic gate operating in an OR logic state under near-infrared irradiation. (RIGHT) Output voltage profile of a switchable ionic logic gate returning to an AND logic state after near-infrared irradiation is turned off.

FIG. 33A. Output voltage variations of a switchable ionic logic gate with a resistor when near-infrared irradiation is applied for 100 s.

FIG. 33B. Output voltage variations of a switchable ionic logic gate with a resistor when near-infrared irradiation is applied for 200 s.

FIG. 33C. Output voltage variations of a switchable ionic logic gate with a resistor when near-infrared irradiation is applied for 300 s.

FIG. 34A. Circuit simulation results of a switchable ionic logic gate exhibiting AND to OR logic transition under cooling and near-infrared heating conditions obtained using LT-SPICE.

FIG. 34B. Circuit simulation results of a switchable ionic logic gate exhibiting AND to OR logic transition under cooling and near-infrared heating conditions obtained using a Falstad simulation program.

FIG. 35A. Circuit simulation results of a switchable ionic logic gate exhibiting NAND to NOR logic transition under cooling and near-infrared heating conditions obtained using LT-SPICE.

FIG. 35B. Circuit simulation results of a switchable ionic logic gate exhibiting NAND to NOR logic transition under cooling and near-infrared heating conditions obtained using a Falstad simulation program.

FIG. 36A. Schematic illustration of an ionic logic gate switching between NAND logic and NOR logic under near-infrared irradiation.

FIG. 36B. Output current response of an ionic logic gate during photothermal heating and cooling, showing logic output states relative to a threshold level.

FIG. 36C. Time-dependent variations in output current of an ionic logic gate during near-infrared irradiation ON and OFF cycles.

FIG. 36D. Time-dependent variations in output voltage of an ionic logic gate during near-infrared irradiation ON and OFF cycles.

FIG. 36E. Schematic illustration of an NIR-responsive ionic logic gate integrated with a light-emitting diode indicator and an Arduino-based control circuit.

FIG. 36F. Photographs showing light-emitting diode ON and OFF states corresponding to NOR and NAND logic operations, respectively, controlled by near-infrared irradiation and subsequent cooling.

### DETAILED DESCRIPTIONS

Hereinafter, embodiments of the present invention will be described in detail with reference to the accompanying drawings. The present invention is capable of various modifications and may take various forms, and specific embodiments are illustrated in the drawings and described in detail herein. However, the present invention is not intended to be limited to the disclosed embodiments, and it should be understood that the present invention includes all modifications, equivalents, and alternatives falling within the spirit and technical scope of the present invention. In describing the drawings, like reference numerals are used to refer to like or similar elements. In the accompanying drawings, dimensions of structures may be exaggerated relative to actual dimensions for clarity of illustration.

The terminology used herein is for the purpose of describing particular embodiments only and is not intended to limit the present invention. As used herein, singular forms include plural forms unless the context clearly indicates otherwise. As used herein, the terms “comprise,” “include,” or “have” specify the presence of stated features, numbers, steps, operations, elements, components, or combinations thereof, but do not preclude the presence or addition of one or more other features, numbers, steps, operations, elements, components, or combinations thereof.

As used in the present specification, the term “about” may refer to a value within approximately ±1%, ±2%, ±3%, ±4%, ±5%, ±6%, ±7%, ±8%, ±9%, or ±10% of a stated numerical value.

Further, descriptions relating to one aspect of the present invention may be equally or similarly applicable to descriptions relating to another aspect of the present invention with respect to the same or similar elements or terminology.

Unless otherwise defined, all terms used herein, including technical and scientific terms, have the same meanings as those commonly understood by a person having ordinary skill in the art to which the present invention pertains. Terms defined in commonly used dictionaries are to be interpreted as having meanings consistent with their meanings in the context of the relevant art and the present disclosure, and are not to be interpreted in an idealized or overly formal sense unless expressly defined otherwise herein.

According to embodiments of the present invention, a composite ionoelastomer material having enhanced ionic mobility may include an ionoelastomer and a positively charged or negatively charged MXene included in the ionoelastomer and interacting with one of a cation and an anion.

In the context of the present specification, the term “ionic mobility” generally refers to an ability of ions to move within a material. Ionic mobility is closely related to ionic conductivity and may affect not only electrical properties but also chemical and physical properties of the material. Materials having high ionic mobility may transmit electrical signals more rapidly, thereby improving performance of electronic devices. Such characteristics may be useful particularly in applications requiring high-speed processing or rapid response, and may contribute to improved efficiency of electronic devices and sensors.

In the context of the present specification, the term “ionoelastomer” generally refers to a composite material in which ionic species are dispersed within a polymer matrix. Such materials may exhibit both ionic conductivity and mechanical stretchability, and thus may be applicable to various electronic devices. Ionoelastomers may play an important role particularly in wearable devices or flexible electronic devices that require mechanical deformation. In addition, since ionoelastomers are solvent-free, they may exhibit high environmental stability and may be suitable for long-term use, while maintaining stable performance under various environmental conditions.

The ionoelastomer may function to modulate electrical characteristics by including both fixed ions and mobile ions. Through this, transmission and conversion of electrical signals may be enabled, thereby improving operating principles of electronic devices. In particular, interactions with fixed ions may increase the number of mobile ions, thereby enhancing ionic conductivity. This may help improve response speed and efficiency of electronic devices and enable high performance in various electronic applications. The ionoelastomer may also provide mechanical flexibility, allowing fabrication in various forms.

The MXene may function to interact with ions within the ionoelastomer and thereby influence ionic mobility. A positively charged MXene may interact with anions, while a negatively charged MXene may interact with cations. Through such interactions, conductivity may be enhanced and electrical characteristics may be strengthened. In addition, MXene may exhibit photothermal properties, thereby providing a possibility of modulating material characteristics using an external light source. This may contribute to increased flexibility and functionality of the material in various applications.

Interactions between the MXene and the ions may include binding based on attractive forces. As a result, ions capable of interacting with the MXene within the ionoelastomer may become relatively immobilized to form dipoles, while mobility of relatively unbound ions may be enhanced. In one embodiment, mobility of ions having the same charge as the MXene included in the ionoelastomer may be enhanced. Such interactions may be particularly advantageous in electronic devices requiring high-frequency response, and may contribute to optimization of performance in applications such as high-speed signal processing.

In one embodiment, the ionoelastomer may include one or more materials selected from the group consisting of 1-ethyl-3-methylimidazolium (3-sulfopropyl) acrylate ([EMIM][SPA]) and 1-[2-acryloyloxyethyl]-3-butylimidazolium bis(trifluoromethane)sulfonimide ([AEBI][TFSI]). However, materials of the ionoelastomer are not limited to the above-described non-limiting examples. In one embodiment, the MXene may include one or more materials selected from the group consisting of Ti₃C₂Tₓ and Ti₃C₂Tₓ surface-treated with polyethyleneimine. However, materials of the MXene are not limited to the above-described non-limiting examples.

Meanwhile, according to embodiments of the present invention, an ionoelastomer-based diode device having enhanced ionic mobility may include an n-side portion including an ionoelastomer and a negatively charged MXene interacting with cations included in the ionoelastomer, and a p-side portion including an ionoelastomer and a positively charged MXene interacting with anions included in the ionoelastomer, the p-side portion being in contact with the n-side portion.

In the context of the present specification, the term “diode” generally refers to an electronic device designed to allow current to flow in only one direction. Typically, a diode has a structure in which a p-type semiconductor or semiconductor-like material is joined to an n-type semiconductor or semiconductor-like material, such that resistance is low and current flows easily under forward bias, while resistance is high and current flow is suppressed under reverse bias. Such characteristics play an important role in signal rectification and logic circuits. In the present invention, the diode is based on an ionic conductor and functions to control ion transport.

The roles of the n-side portion and the p-side portion are to transport negatively charged ions and positively charged ions, respectively, thereby implementing rectifying characteristics of the diode. The n-side portion includes negatively charged ionic species, and the p-side portion includes positively charged ionic species, and current flow is controlled through junction of the two portions.

In one embodiment, the diode device may further include a first electrode in contact with the n-side portion, and a second electrode spaced apart from the first electrode and in contact with the p-side portion. The first electrode and the second electrode may function to control current flow and to implement electrical characteristics of the diode device. The first electrode may be connected to the n-side portion, and the second electrode may be connected to the p-side portion, such that a voltage is applied across the ionoelastomer diode. These electrodes are configured to apply electrical signals to the diode and to transmit output signals to an external circuit

In one embodiment, the ionoelastomer of the n-side portion may include one or more materials selected from the group consisting of 1-[2-acryloyloxyethyl]-3-butylimidazolium bis(trifluoromethane)sulfonimide ([AEBI][TFSI]). However, the material of the ionoelastomer of the n-side portion is not limited to the above-described non-limiting example. Other possible ionoelastomer materials include, but are not limited to, 1-butyl-3-methylimidazolium hexafluorophosphate ([BMIM][PF₆]), 1-ethyl-3-methylimidazolium trifluoromethanesulfonate ([EMIM][OTf]), 1-propyl-3-methylimidazolium bis(trifluoromethane)sulfonimide ([PMIM][TFSI]), 1-hexyl-3-methylimidazolium hexafluorophosphate ([HMIM][PF₆]), 1-octyl-3-methylimidazolium bis(trifluoromethane)sulfonimide ([OMIM][TFSI]), 1-dodecyl-3-methylimidazolium bis(trifluoromethane)sulfonimide ([DMIM][TFSI]), 1-benzyl-3-methylimidazolium hexafluorophosphate ([BzMIM][PF₆]), 1-allyl-3-methylimidazolium bis(trifluoromethane)sulfonimide ([AlMIM][TFSI]), 1-ethoxy-3-methylimidazolium bis(trifluoromethane)sulfonimide ([EtOMIM][TFSI]), 1-(2-methoxyethyl)-3-methylimidazolium bis(trifluoromethane)sulfonimide ([MeOEtMIM][TFSI]), 1-(2-hydroxyethyl)-3-methylimidazolium bis(trifluoromethane)sulfonimide ([HEMIM][TFSI]), 1-butyl-1-methylpiperidinium bis(trifluoromethane)sulfonimide ([BMP][TFSI]), 1-hexyl-1-methylpiperidinium bis(trifluoromethane)sulfonimide ([HMP][TFSI]), 1-butyl-1-methylpyrrolidinium bis(trifluoromethane)sulfonimide ([BMPy][TFSI]), 1-hexyl-1-methylpyrrolidinium bis(trifluoromethane)sulfonimide ([HMPy][TFSI]), 1-ethyl-3-methylpyrrolidinium bis(trifluoromethane)sulfonimide ([EMPy][TFSI]), 1-propyl-3-methylpyrrolidinium bis(trifluoromethane)sulfonimide ([PMPy][TFSI]), 1-ethyl-3-methylpiperidinium bis(trifluoromethane)sulfonimide ([EMP][TFSI]), 1-propyl-3-methylpiperidinium bis(trifluoromethane)sulfonimide ([PMP][TFSI]), and 1-butyl-3-methylquinolinium bis(trifluoromethane)sulfonimide ([BMQ][TFSI]).

In one embodiment, the ionoelastomer of the p-side portion may include one or more materials selected from the group consisting of 1-ethyl-3-methylimidazolium (3-sulfopropyl) acrylate ([EMIM][SPA]). However, the material of the ionoelastomer of the p-side portion is not limited to the above-described non-limiting example. Other possible ionoelastomer materials include, but are not limited to, 1-ethyl-3-methylimidazolium ethyl sulfate ([EMIM][EtSO₄]), 1-ethyl-3-methylimidazolium methanesulfonate ([EMIM][MeSO₃]), 1-ethyl-3-methylimidazolium acetate ([EMIM][OAc]), 1-ethyl-3-methylimidazolium diethyl phosphate ([EMIM][DEP]), 1-ethyl-3-methylimidazolium trifluoroacetate ([EMIM][TFA]), 1-ethyl-3-methylimidazolium chloride ([EMIM][Cl]), bromide ([EMIM][Br]), iodide ([EMIM][I]), bis(trifluoromethane)sulfonimide ([EMIM][TFSI]), bis(octafluoropentyl)phosphate ([EMIM][FAP]), heptafluorobutyrate ([EMIM][HFB]), tetrafluoroborate ([EMIM][BF₄]), difluorophosphate ([EMIM][DFP]), nitrate ([EMIM][NO₃]), cyanobromide ([EMIM][CNBr]), hydrogen sulfate ([EMIM][HSO₄]), trifluoromethanesulfonate ([EMIM][OTf]), dicyanoimidazolide ([EMIM][DCN]), phosphate ([EMIM][PO₄]), and oxodifluoroborate ([EMIM][ODFB]).

In one embodiment, the MXene included in the n-side portion may include one or more materials selected from the group consisting of Ti₃C₂Tₓ. Such MXene may be a negatively charged MXene. However, materials of the negatively charged MXene are not limited to the above-described non-limiting example. Other possible negatively charged MXenes include, but are not limited to, Ti₂C, Ti₃CN, Nb₂C, V2C, Mo₂C, Cr₂C, Zr₂C, Hf₂C, Ta₂C, Sc₂C, Y₂C, W₂C, Mn₂C, Fe₂C, Co₂C, Ni₂C, Cu₂C, Zn₂C, Ga₂C, In₂C, and derivatives thereof.

In one embodiment, the MXene included in the p-side portion may include one or more materials selected from the group consisting of Ti₃C₂Tₓ surface-treated with polyethyleneimine. Such MXene may be a positively charged MXene. However, materials of the positively charged MXene are not limited to the above-described non-limiting example. Other possible positively charged MXenes include, but are not limited to, PEI surface-treated Ti₂C, Ti₃CN, Nb₂C, V2C, Mo₂C, Cr₂C, Zr₂C, Hf₂C, Ta₂C, Sc₂C, Y₂C, W₂C, Mn₂C, Fe₂C, Co₂C, Ni₂C, Cu₂C, Zn₂C, Ga₂C, In₂C, and derivatives thereof.

In one embodiment, the MXene included in the n-side portion or the p-side portion may be included in an amount of about 0.5 to 3 wt %. Although the scope of the present invention is not limited to the above-described MXene content, referring to embodiments described below, ionic conductivity and physical properties may be optimized within the above-described MXene content range. For example, when the MXene content is about 0.5 wt % or less, effective dispersion of MXene may be difficult, resulting in limited improvement in conductivity, whereas when the MXene content exceeds about 3 wt %, mechanical flexibility of the ionoelastomer may be reduced. Accordingly, an MXene content of about 0.5 to 3 wt % may help balance ionic conductivity and physical properties. Within this content range, the composite material may maintain excellent electrical performance while retaining sufficient flexibility, thereby being effectively applicable to various applications.

Meanwhile, according to embodiments of the present invention, a light-responsive gate whose characteristics are adjustable by light may include a diode device including an n-side portion including an ionoelastomer and a negatively charged MXene interacting with cations included in the ionoelastomer, and a p-side portion including an ionoelastomer and a positively charged MXene interacting with anions included in the ionoelastomer, the p-side portion being in contact with the n-side portion. The light-responsive gate may further include two input electrodes in contact with the p-side portion, and an output electrode spaced apart from the input electrodes and in contact with the n-side portion.

The input electrodes and the output electrode may function to receive and output electrical signals, respectively, such that the diode device can perform a desired function. The input electrodes may receive electrical signals from an external circuit and transmit the signals to the p-side portion of the diode device, thereby inducing ion transport and enabling current flow. In contrast, the output electrode may function to transmit an electrical signal generated in the diode device to an external circuit. Through the arrangement and interaction of these electrodes, a logical state of the gate may be controlled, and various logic operations may be performed by modulating characteristics of the diode through light irradiation. Accordingly, flexible and efficient control may be achieved in various electronic circuits, and significant advantages may be provided in applications requiring high-speed signal processing and accurate logic operations.

In the context of the present specification, the term “characteristics adjustable by light” may refer to a change in physical and/or chemical properties of the gate depending on the presence or absence of light irradiation and/or the amount of light irradiation. For example, according to one embodiment of the present invention, when light is irradiated, resistance of the diode device may be reduced. Such resistance reduction may result from a temperature increase induced by a photothermal effect of MXene upon light irradiation, and the temperature increase may enhance ion mobility, thereby improving ionic conductivity. As a result, under light irradiation, the diode device may exceed a threshold voltage even with a smaller or fewer input signals, thereby enabling a transition from an AND gate mode to an OR gate mode. Such characteristics may be advantageously applied to various light-based electronic devices and may provide an innovative solution for high-speed signal processing and precise control.

In one embodiment, the diode device may include the ionoelastomer-based diode device having enhanced ionic mobility according to the embodiments of the present invention described above. In such a diode device, negatively charged MXene and positively charged MXene may be included in the n-side portion and the p-side portion, respectively, thereby improving electrical characteristics. Due to the combination of the ionoelastomer and MXene, ion mobility may be significantly increased, which may contribute to optimization of electrical performance of the diode device.

In particular, due to resistance reduction upon light irradiation, the gate may function both as an AND gate and an OR gate. For example, when light is not irradiated or when the amount of light irradiation is relatively low, resistance may be high, such that signals must be applied to two input electrodes to exceed a threshold voltage, thereby operating as an AND gate. In contrast, when the amount of light irradiation is relatively high, resistance may be reduced, such that even a signal applied to a single input electrode may readily exceed the threshold voltage, thereby operating as an OR gate. This enables flexible switching of an operation mode of the diode device by adjusting intensity of a light source, and may facilitate execution of more complex operations in various logic circuits. Such functionality may improve efficiency of high-performance computing systems and smart electronic devices, and may significantly increase freedom in circuit design. Furthermore, by enabling real-time response to environmental changes or external signals, the present invention may make an important contribution to development of adaptive electronic systems.

Meanwhile, according to embodiments of the present invention, a light-controlled device may include a gate whose characteristics are adjustable by light, and a light source configured to irradiate light onto the gate. In one embodiment, the gate may include the gate according to the embodiments of the present invention described above. Accordingly, electrical characteristics and performance of the gate may be dynamically adjusted depending on irradiation conditions of the light source. This provides a possibility of optimizing operation of electronic devices in real time through external optical control. Such functionality may enhance energy efficiency in various electronic devices and enable rapid adaptation to environmental changes, thereby playing an important role in development of high-performance smart electronic systems. In addition, the light-controlled device may contribute to flexible and adaptive electronic circuit design in applications such as wearable devices and Internet of Things (IoT) devices.

The light source may function to irradiate light onto the gate to modulate characteristics of the diode device. Specifically, the light source may emit light of a specific wavelength to induce a photothermal effect of MXene, thereby increasing a temperature of the ionoelastomer. Such temperature increase may enhance ion mobility and thereby regulate current flow. By adjusting irradiation conditions of the light source, electrical characteristics of the gate may be finely controlled, which may allow the device to exhibit optimal performance under various environments. Accordingly, the light source may play an important role in real-time control of operation of electronic devices and in implementing various operation modes depending on applications. Through this, high efficiency and adaptability may be provided in smart electronic systems and various high-performance electronic devices.

The device may be flexible and stretchable, and may be formed of biocompatible materials, such that the device may be used in smart watches, smart clothing, assistive devices, and the like, and may function as a human-interactive device. In contrast, previously reported tunable logic gates have employed toxic materials such as perovskites and generally lack flexibility or stretchability, making them unsuitable for use as human-interactive devices.

Furthermore, since portability is important for such human-interactive devices, miniaturization and circuit simplification are required. The device proposed in the present invention is capable of functioning as both an AND gate and an OR gate depending on near-infrared light modulation even as a single device. Accordingly, unlike conventional circuit technologies that control AND gates and OR gates using complex structures, the present invention may significantly simplify circuit configurations. By utilizing the technology proposed in the present invention, it is expected that a tunable logic gate capable of miniaturization and circuit simplification may be realized.

Hereinafter, examples of the present invention will be described. However, the examples described below are merely some embodiments of the present invention, and the scope of the present invention is not limited to the following examples.

### Experimental Example: Fabrication and Characterization of AT-NMXene and ES-PMXene

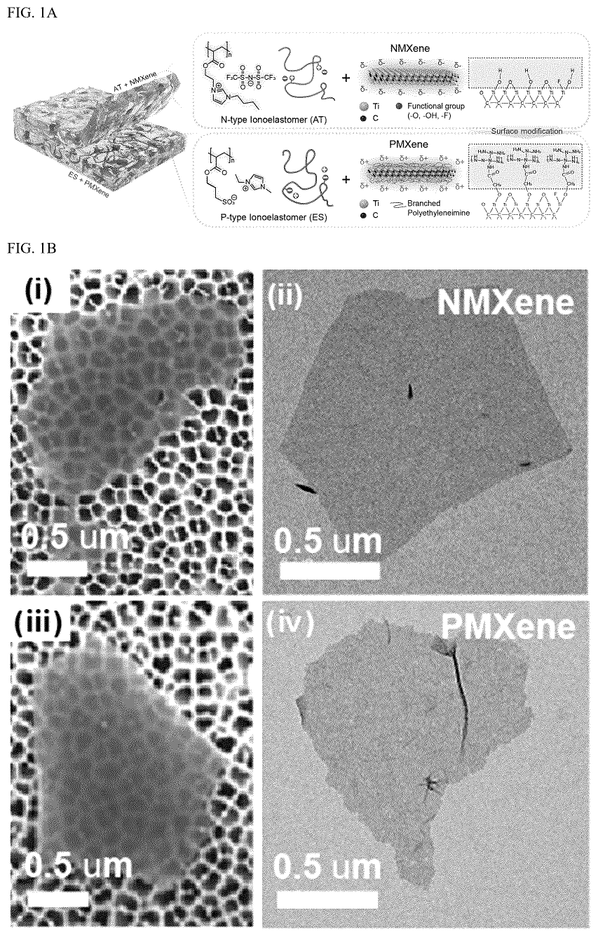

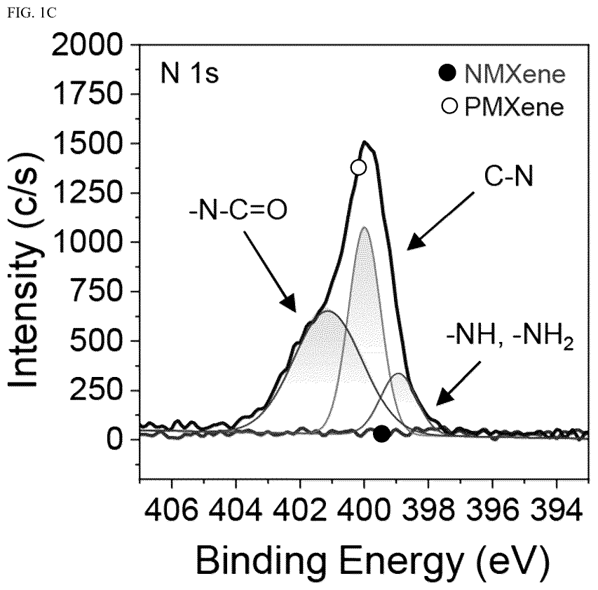

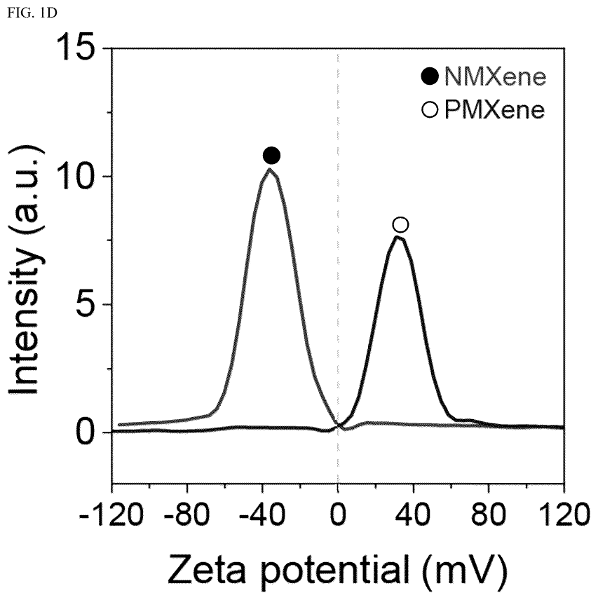

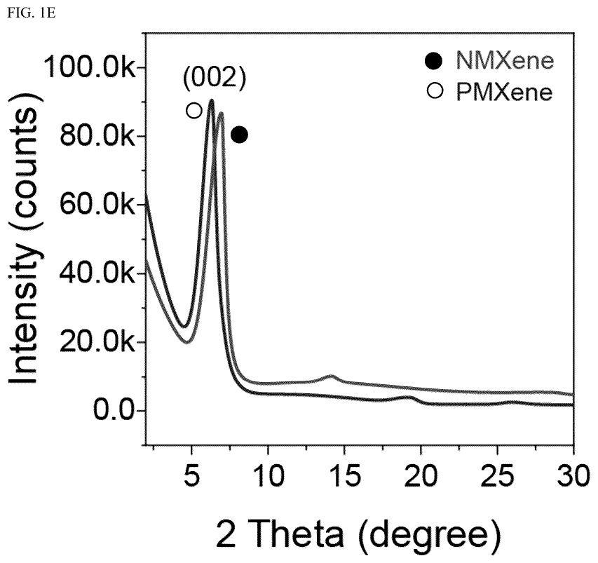

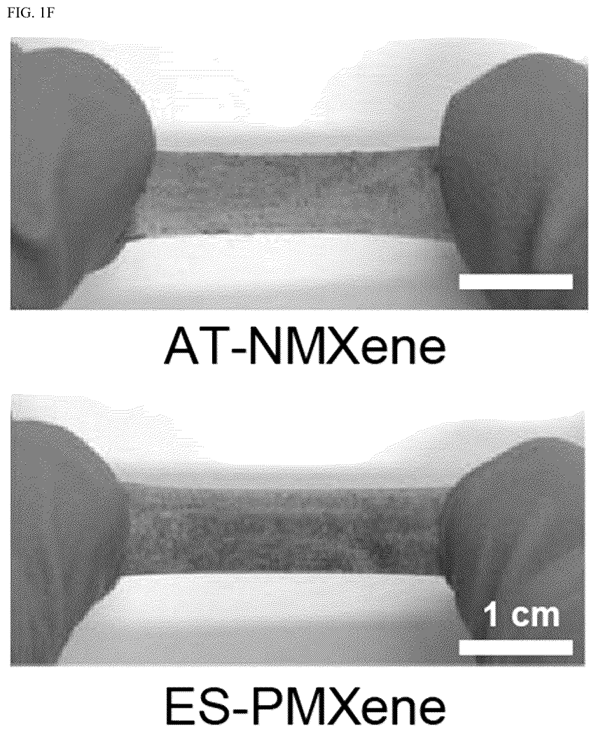

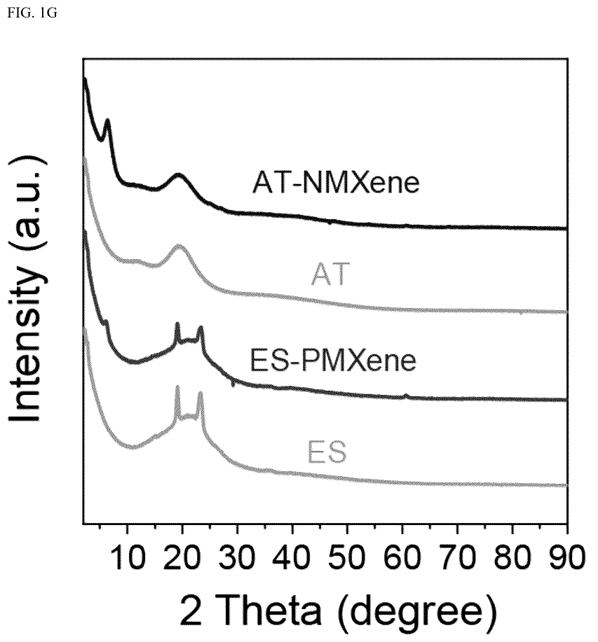

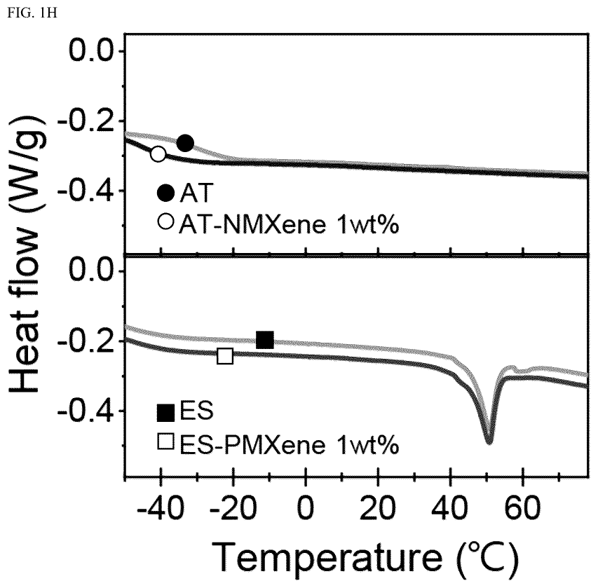

FIG. 1A illustrates n-type and p-type ionoelastomers with their corresponding mobile anions and cations, respectively. 1-[2-acryloyloxyethyl]-3-butylimidazolium bis(trifluoromethane) sulfonimide ([AEBI][TFSI], denoted as AT) was selected as the n-type ionoelastomer, in which the [TFSI]⁻ anions were mobile while the [AEBI] cations were fixed to the polymer backbone. Similarly, 1-ethyl-3-methyl imidazolium (3-sulfopropyl) acrylate ([EMIM][SPA], denoted as ES) was selected as the p-type ionoelastomer, in which the [EMIM]⁺ cations were mobile while the [SPA]⁻ anions were fixed to the polymer backbone. Conventional Ti₃C₂Tₓ MXene nanosheets containing abundant functional groups, including ═O, OH, and F, and having negative dipoles render the surface of the MXene nanosheets negatively charged, and such nanosheets are denoted as NMXene, as schematically illustrated in FIG. 1A. Scanning electron microscopy and transmission electron microscopy confirmed the two-dimensional structure of the NMXene nanosheets, as shown in the upL⁻¹eft and upper right images of FIG. 1B, respectively.

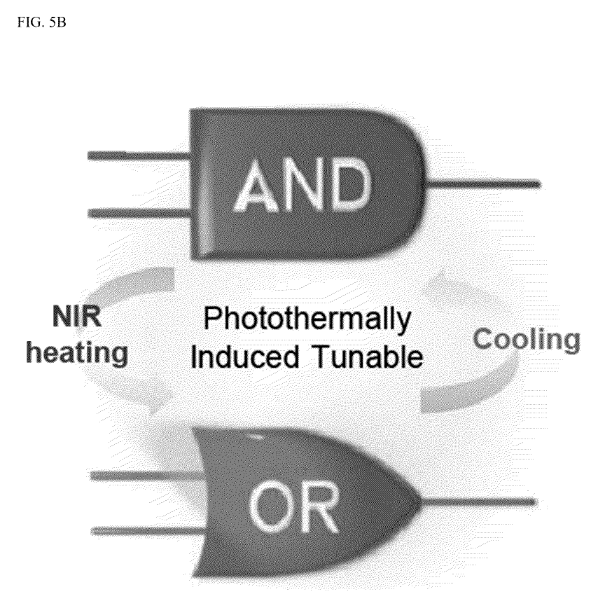

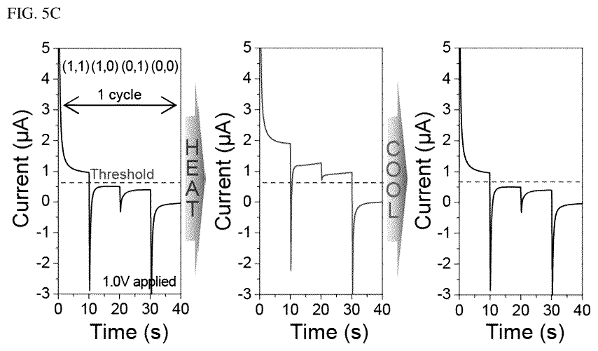

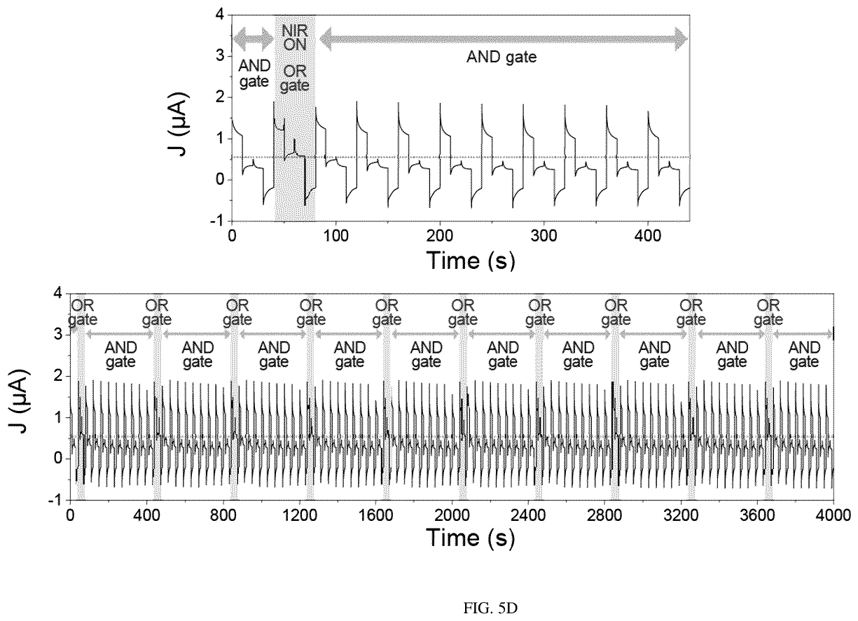

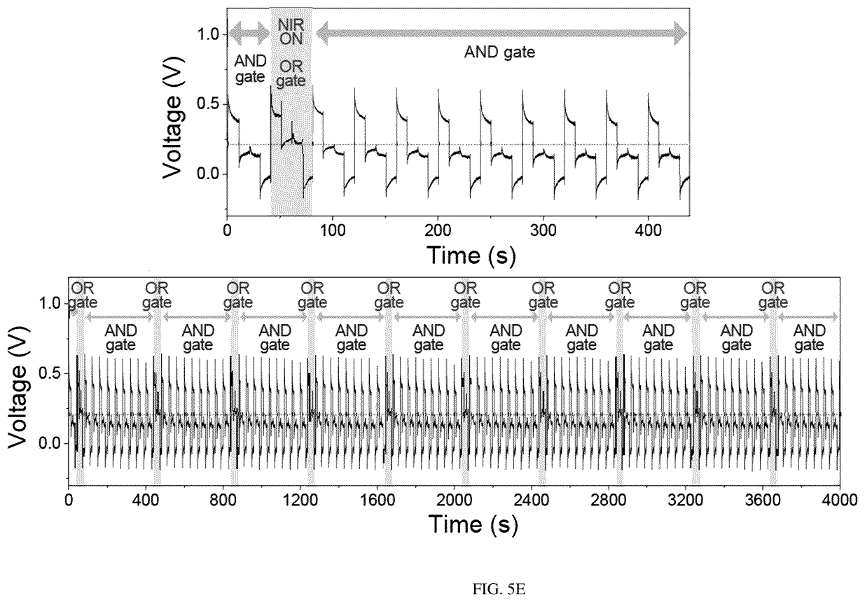

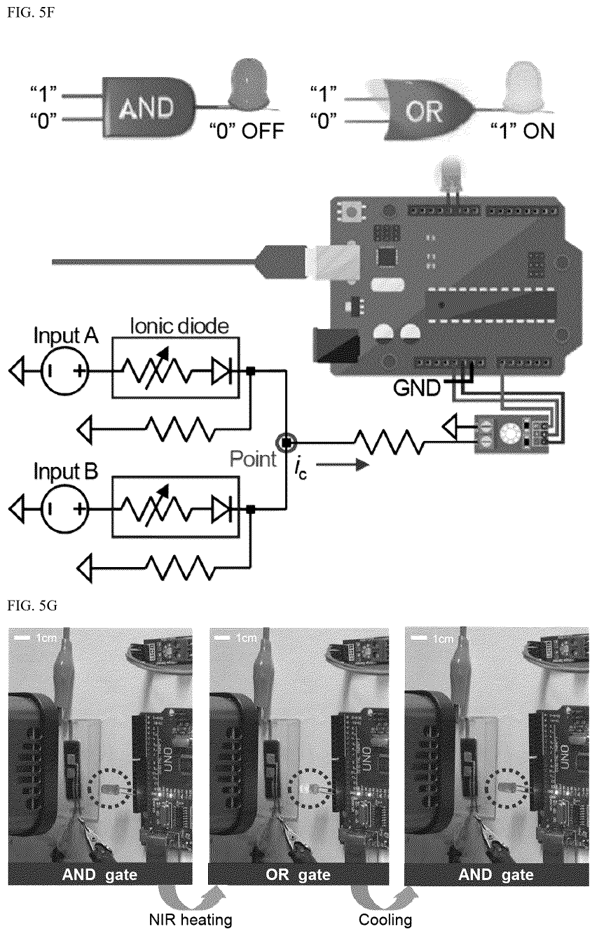

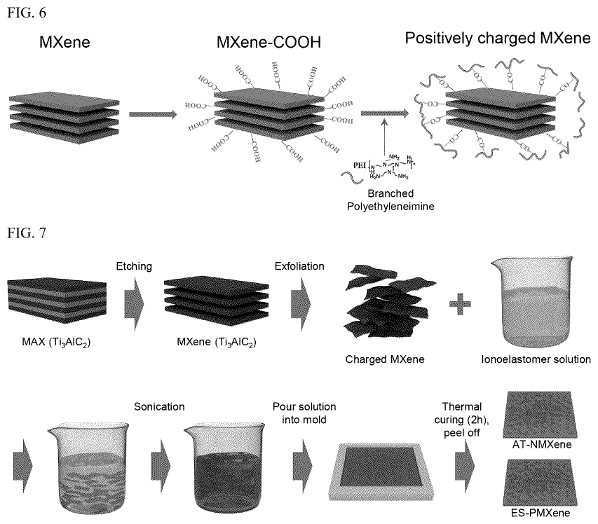

In order to fabricate MXene nanosheets having a positively charged surface potential, denoted as PMXene, the pristine functional groups (OH) of NMXene were replaced with carboxyl groups (COOH), followed by mixing with branched poly(ethylenimine) (BPEI), as illustrated in FIG. 1A. A condensation reaction between BPEI and the carboxyl groups occurred on NMXene, thereby rendering the surface of the MXene positively charged due to the amine groups of PEI, as depicted in FIG. 1A. Detailed synthetic procedures for NMXene and PMXene are shown in FIGS. 6 and 7. The two-dimensional structure of PMXene was also confirmed by scanning electron microscopy and transmission electron microscopy, and the results are shown in the lower left and lower right images of FIG. 1B, respectively.

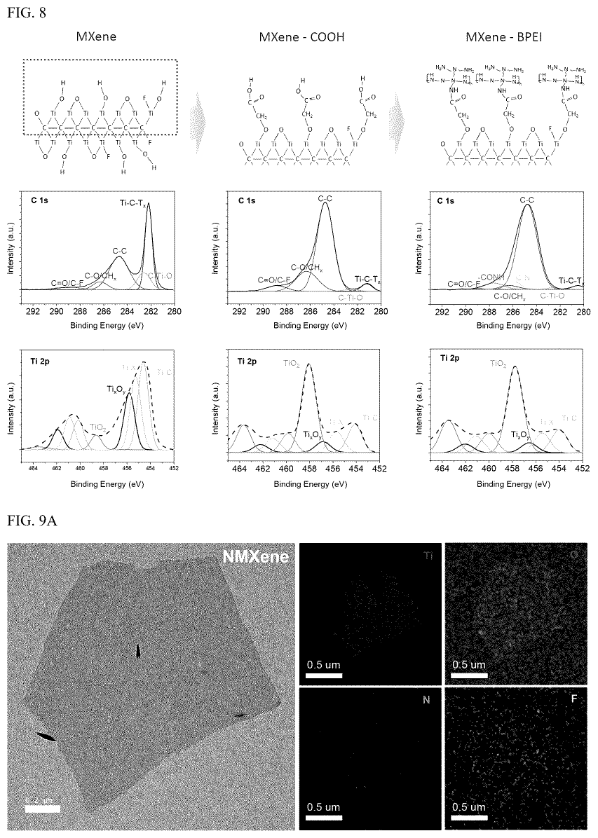

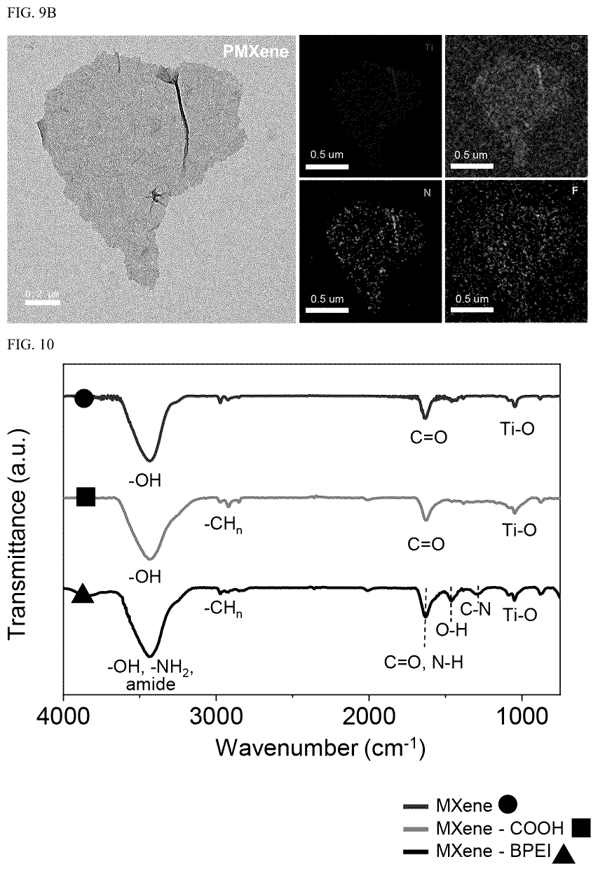

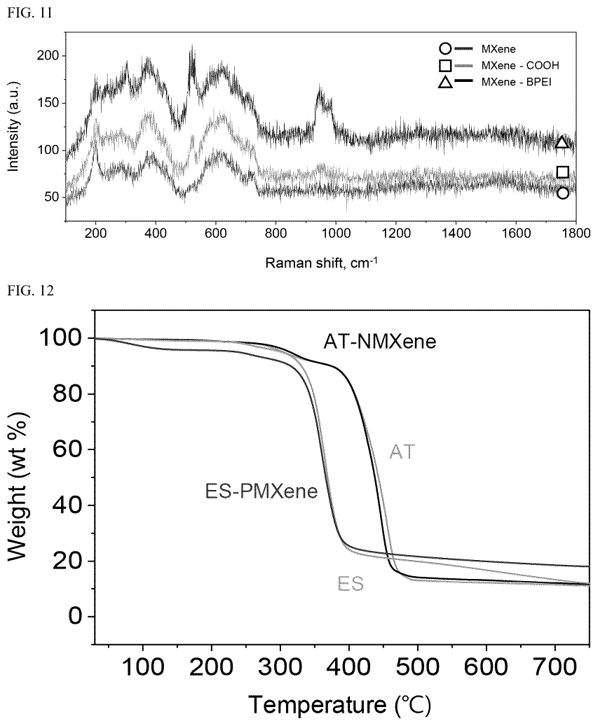

The synthesis of PMXene nanosheets was confirmed by X-ray photoelectron spectroscopy analysis, and the results are shown in FIG. 1C. The N 1s region was resolved into three peaks at 401.16 eV, 400.01 eV, and 398.93 eV, corresponding to N—C═O, C—N, and NH or NH2 groups, respectively. The presence of amide groups confirmed the synthesis of BPEI-functionalized PMXene, as further illustrated in FIG. 8. In addition, characteristic X-ray spectra corresponding to Ti, O, and F were obtained for NMXene in energy-dispersive X-ray spectroscopy, as shown in FIGS. 9A and 9B. In the case of PMXene, additional X-ray emission originating from N was detected due to modification with BPEI. Fourier-transform infrared spectroscopy and Raman spectroscopy further supported the formation of PMXene, as shown in FIGS. 10 and 11. The negatively and positively charged surfaces of NMXene and PMXene were also evidenced by zeta potential measurements, in which NMXene and PMXene exhibited potential values of −36 mV and +32 mV, respectively, as shown in FIG. 1D.

Both MXenes were further examined by high-resolution X-ray diffraction, and the results are shown in FIG. 1E. Strong (002) reflections at 6.98° and 6.34° were observed in the X-ray diffraction patterns of NMXene and PMXene, respectively. The increased (002) spacing of PMXene was attributed to intercalation of NMXene with the long and flexible BPEI.

NMXene and PMXene were mixed with AT and ES, respectively, thereby forming two ionoelastomer composites denoted as AT-NMXene and ES-PMXene, as shown in the photographs in FIG. 1F. The X-ray diffraction results in FIG. 1G show that the (002) reflections of NMXene and PMXene were maintained in AT-NMXene and ES-PMXene. The reflections observed at approximately 19.1° and 23.3° correspond to the (120) and (032) reflections of poly(ethylene glycol) diacrylate crystals, respectively. In the case of AT and AT-NMXene, reflections from poly(ethylene glycol) diacrylate were rarely observed due to a substantial reduction in crystallinity arising from ion-dipole interactions between the polycation and oxygen.

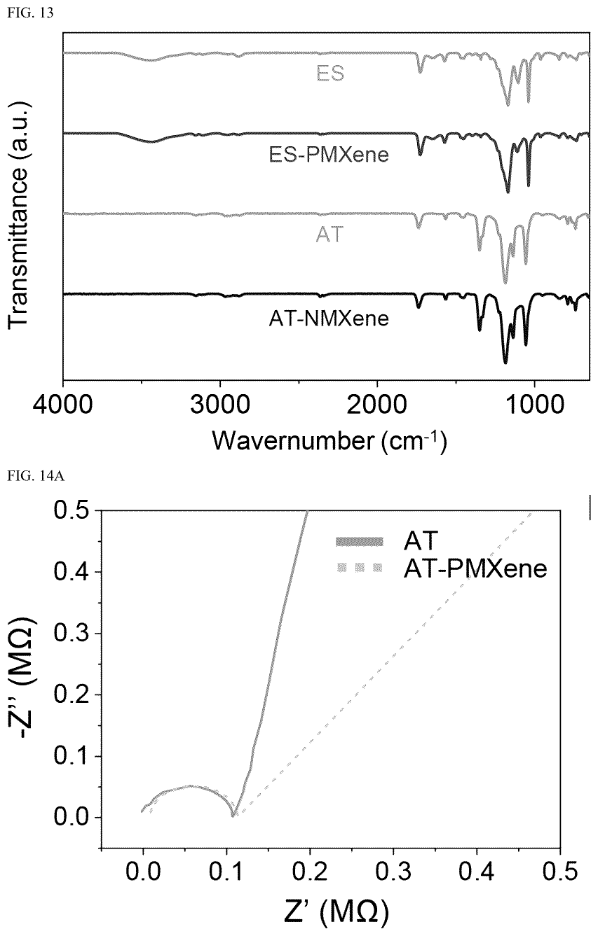

The thermal properties of AT-NMXene and ES-PMXene were examined using differential scanning calorimetry, and the results are shown in FIG. 1H. The melting temperatures of poly(ethylene glycol) diacrylate crystals in ES and ES-PMXene were approximately 50.73 °C and 50.75 °C, respectively. No melting peaks were observed for AT or AT-NMXene. In addition, thermogravimetric analysis results showed that ES and ES-PMXene contained approximately 2.68% residual water due to the hygroscopic nature of ES, as shown in FIGS. 12 and 13. In contrast, water was largely not detected in AT and AT-NMXene due to the presence of fluorinated [TFSI]⁻ anions.

The mechanical properties of AT-NMXene and ES-PMXene were evaluated by tensile stress-strain experiments, as shown in FIG. 1I. When MXene was incorporated into the ionoelastomers, stretchability decreased as MXene acted as a stress concentration site, whereas the modulus of the samples increased slightly due to additional interactions provided by the MXene nanosheets. A maximum tensile strain of approximately 450% was obtained for both AT-NMXene and ES-PMXene containing 1 wt % NMXene and 1 wt % PMXene.

### Experimental Example: Ionic Properties of AT-NMXene and ES-PMXene

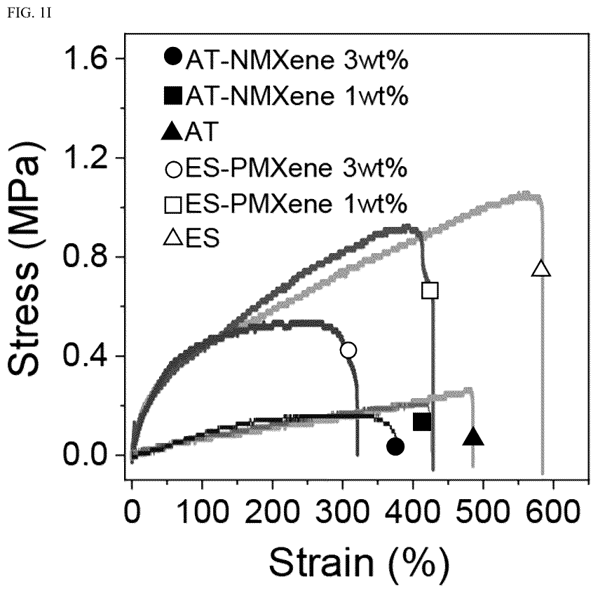

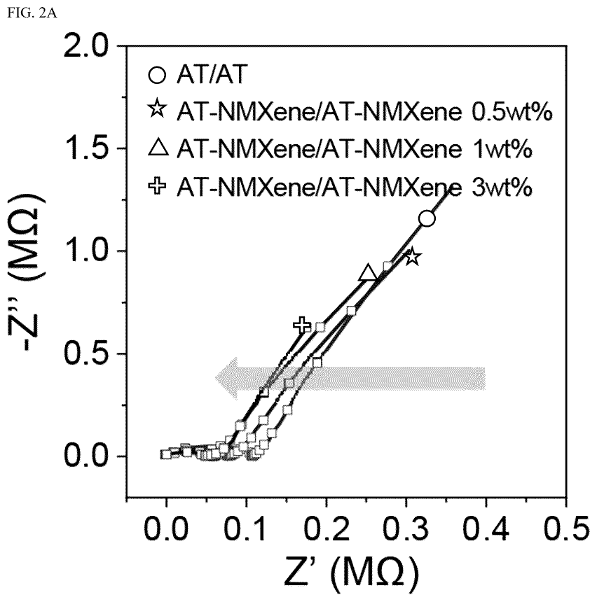

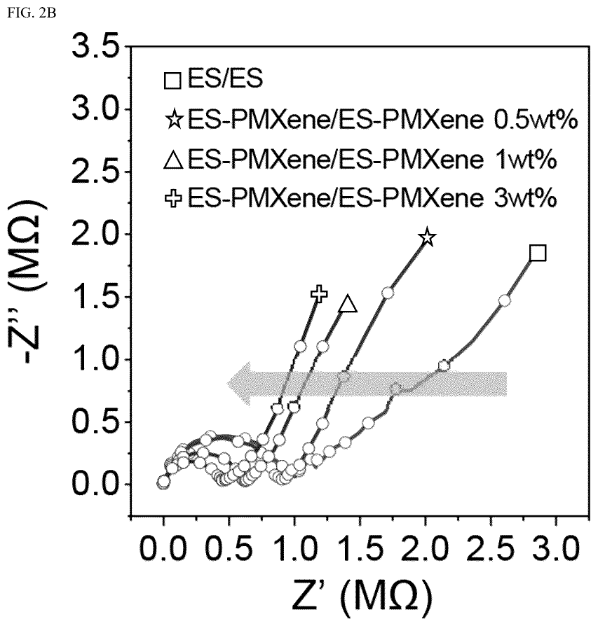

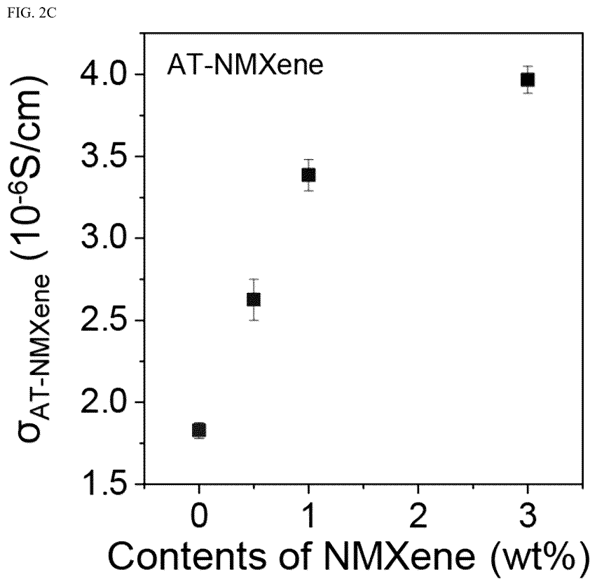

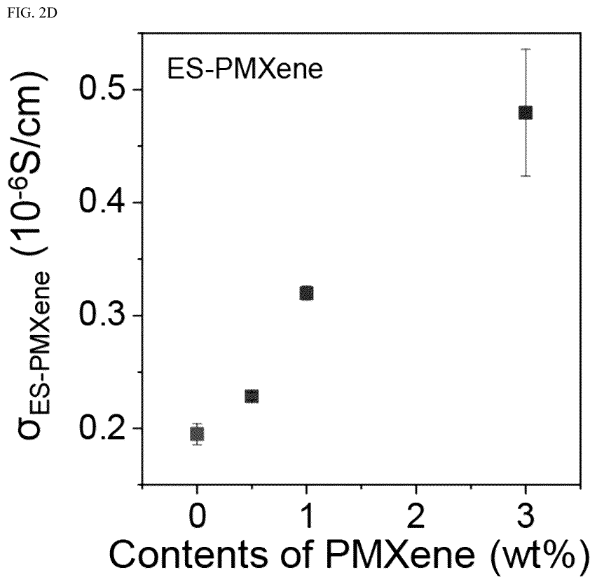

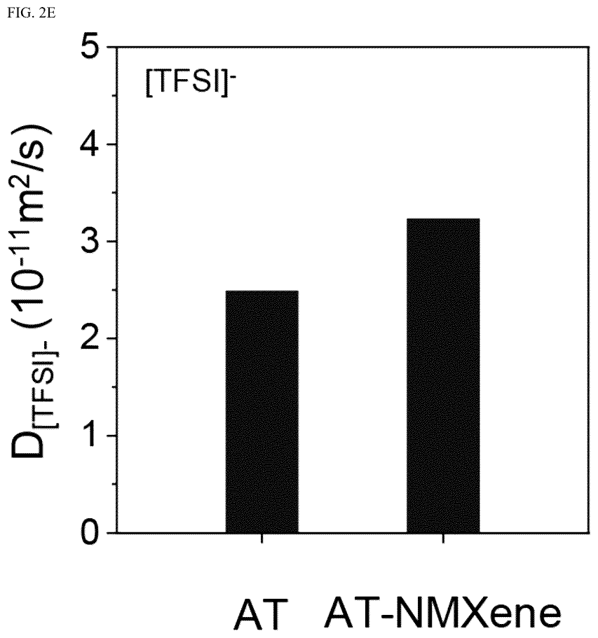

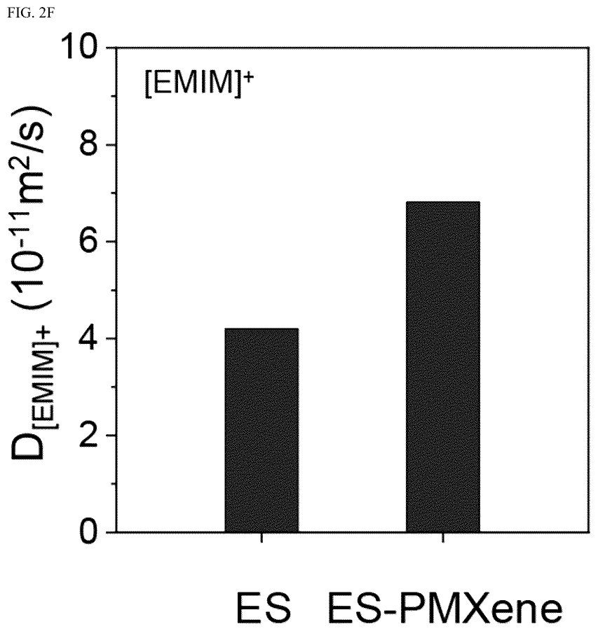

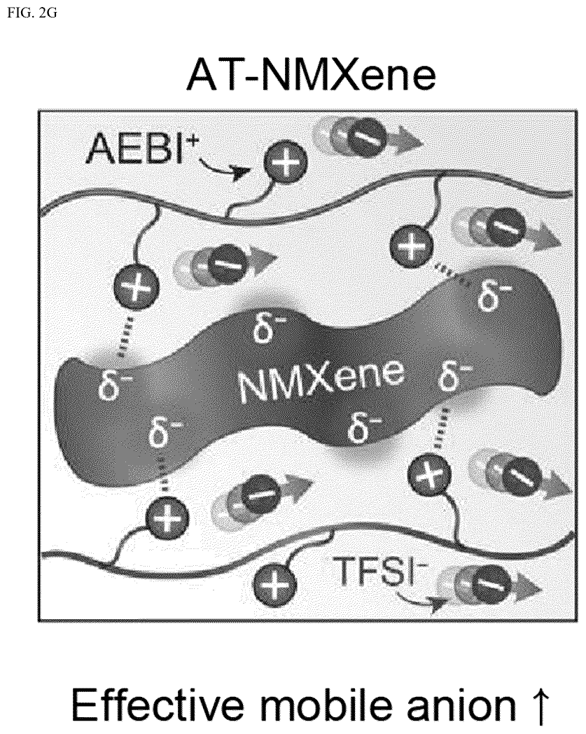

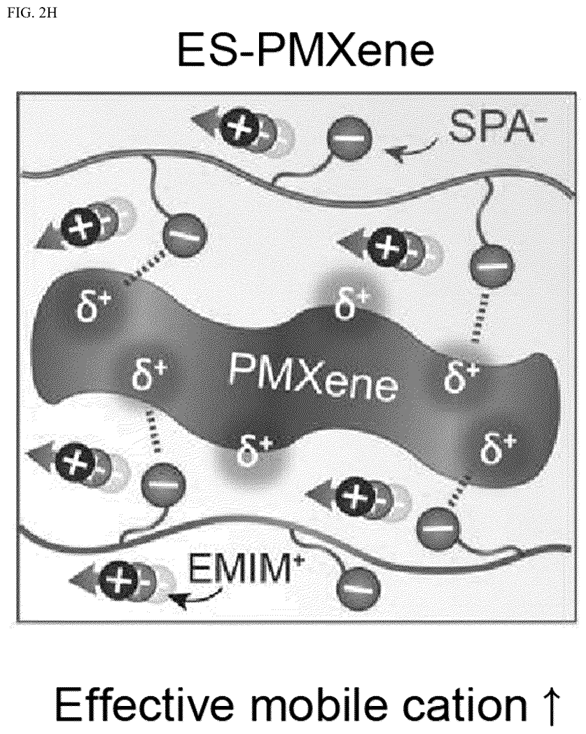

The ionic conductivities of AT-NMXene and ES-PMXene were evaluated using alternating current impedance measurements, and the results are shown in FIGS. 2A and 2B. A Nyquist plot was used to determine the bulk resistance (R_{B}) of each sample, and the ionic conductivity (σ) was calculated from the measured bulk resistance according to the relationship σ=ρ⁻¹=l·A⁻¹·R_{B}⁻¹, where ρ represents resistivity, l represents the thickness of the sample (l=500 um), and A represents the area (A=0.25 cm²). The bulk resistance of AT-NMXene and ES-PMXene decreased as the amounts of NMXene and PMXene increased, respectively, thereby causing the ionic conductivities of both samples to increase with increasing MXene content. As shown in FIG. 2C, the ionic conductivity of AT increased from 1.829×10⁻⁶ S/cm to approximately 2.63×10⁻⁶ S/cm, 3.39×10⁻⁶ S/cm, and 3.97×10⁻⁶ S/cm upon the addition of 0.5 wt %, 1 wt %, and 3 wt % NMXene, respectively. Similarly, the ionic conductivity of ES increased from 0.19×10⁻⁶ S/cm to approximately 0.23×10⁻⁶ S/cm, 0.32×10⁻⁶ S/cm, and 0.48×10⁻⁶ S/cm with the incorporation of 0.5 wt %, 1 wt %, and 3 wt % PMXene, respectively, as shown in FIG. 2D.

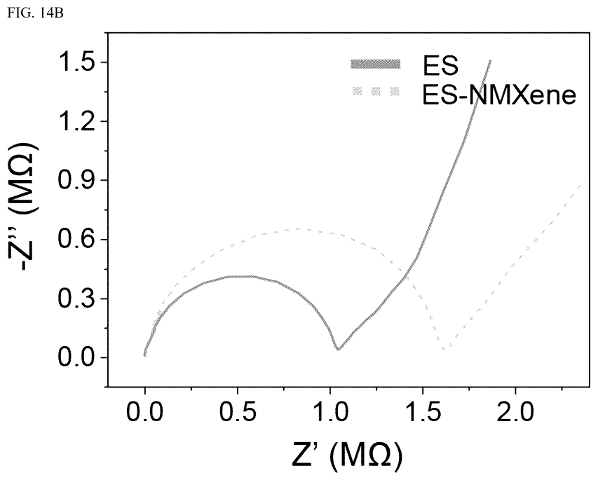

It is noted that when NMXene was mixed with ES and PMXene was mixed with AT, the bulk resistance values of both samples were rarely changed, indicating that percolation of the added MXene nanosheets did not occur in either composite at the low content of conductive MXene moieties of 1 wt %, as shown in FIG. 14. These results indicate that the reduction in resistance of AT-NMXene and ES-PMXene resulted from additional mobile ions generated by specific interactions between AT and NMXene and between ES and PMXene, as described below.

The enhanced ionic conductivities of AT-NMXene and ES-PMXene resulting from the presence of additional mobile ions were further supported by diffusion ordered spectroscopy measurements, and the results are shown in FIGS. 2E and 2F, respectively. The self-diffusion coefficients of mobile [TFSI]⁻ anions and [EMIM]⁺ cations in AT and ES, respectively, were determined using the Stejskal-Tanner equation. The diffusion coefficient of [TFSI]⁻ anions in AT-NMXene increased from 2.49×10⁻¹¹ to 3.24×10⁻¹¹ when 1 wt % NMXene was incorporated into AT, corresponding to an increase of approximately 29.70%. Similarly, the diffusion coefficient of [EMIM]⁺ cations in ES-PMXene increased from 4.21×10⁻¹¹ to 6.810×10⁻¹¹ when 1 wt % PMXene was incorporated into ES, corresponding to an increase of approximately 61.87%. These results indicate that the addition of NMXene and PMXene to AT and ES, respectively, enhanced the mobilities of [TFSI]⁻ anions and [EMIM]⁺ cations.

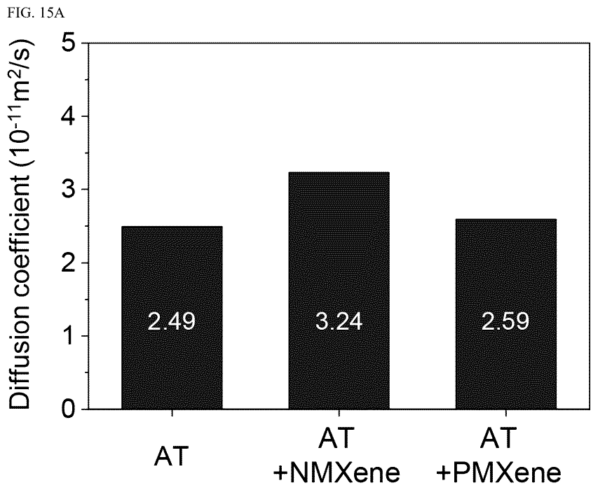

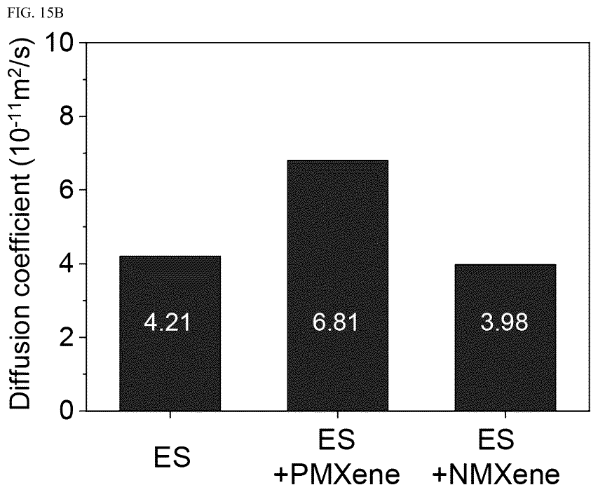

The difference in the degree of enhancement in ion diffusivity between the ES-PMXene system and the AT-NMXene system may arise from differences in the degree of crystallinity of ES-based and AT-based composites. As described with reference to FIGS. 1F and 1G, the ES-based system exhibits relatively higher crystallinity due to the presence of poly(ethylene glycol) diacrylate cross-linkers, whereas in the AT-based system, ether groups of poly(ethylene glycol) diacrylate interact with fixed cations through ion-dipole interactions, resulting in a more amorphous structure. Consequently, the ES matrix exhibits intrinsically lower ionic conductivity than the AT matrix. Upon incorporation of MXene, interactions between MXene and the polymer backbone may disrupt crystalline domains, thereby enhancing ion mobility. This effect may be more pronounced in the ES-PMXene system, in which the initial crystallinity is higher and thus more susceptible to disruption, resulting in a greater increase in [EMIM]⁺ cation diffusivity than [TFSI]⁻ anion diffusivity. This tendency is consistent with the ionic conductivity results shown in FIGS. 2A and 2B. Notably, both the diffusion coefficient of [TFSI]⁻ anions and the diffusion coefficient of [EMIM]⁺ cations were rarely changed when PMXene and NMXene were added to AT and ES, respectively, as shown in FIG. 15.

The enhanced ionic conductivities of both AT-NMXene and ES-PMXene originated from increased concentrations and mobilities of free mobile ions due to ion-dipole interactions between fixed cations in AT and NMXene and between fixed anions in ES and PMXene, as schematically illustrated in FIGS. 2G and 2H, respectively. In addition, the increased concentration of mobile ions enhanced the electric double-layer capacitance of AT-NMXene and ES-PMXene, as shown in FIG. 16.

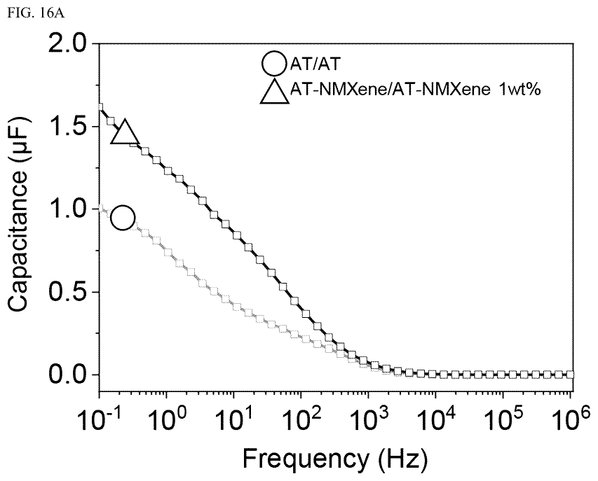

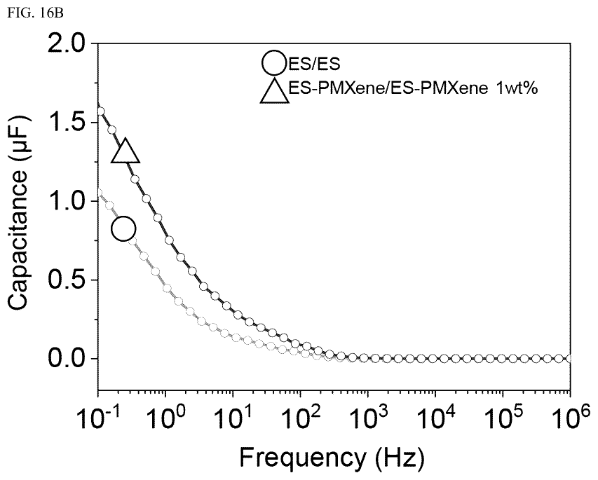

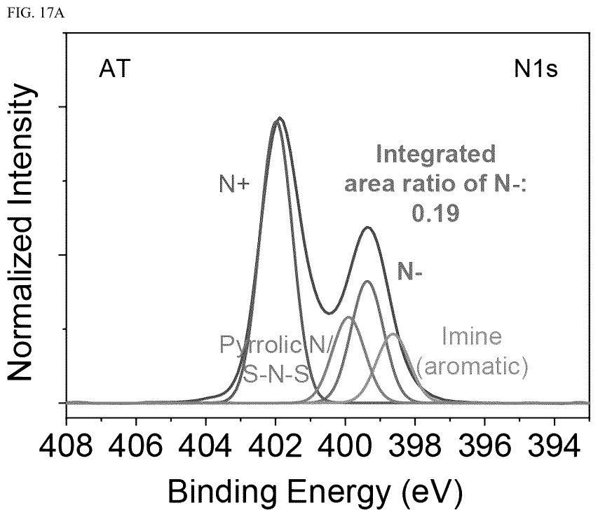

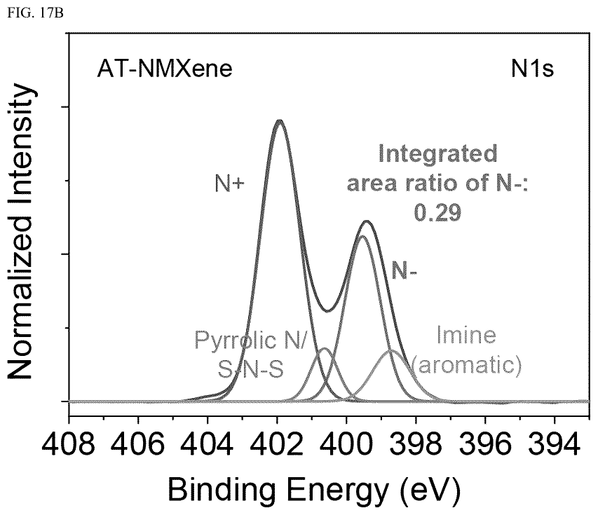

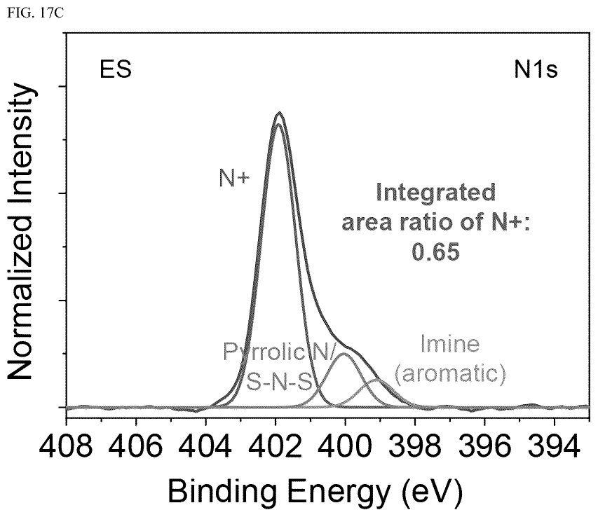

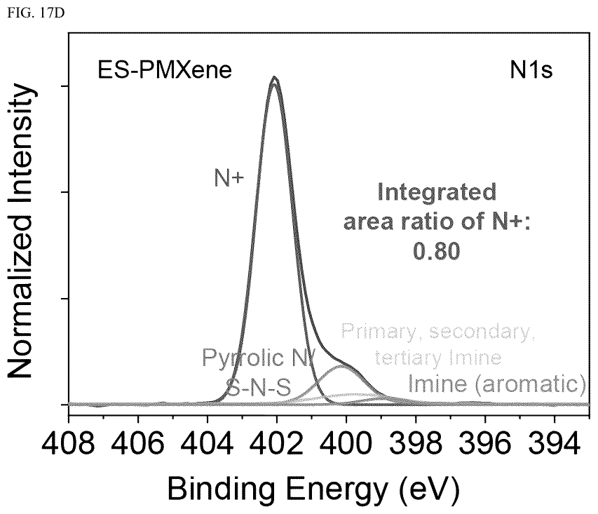

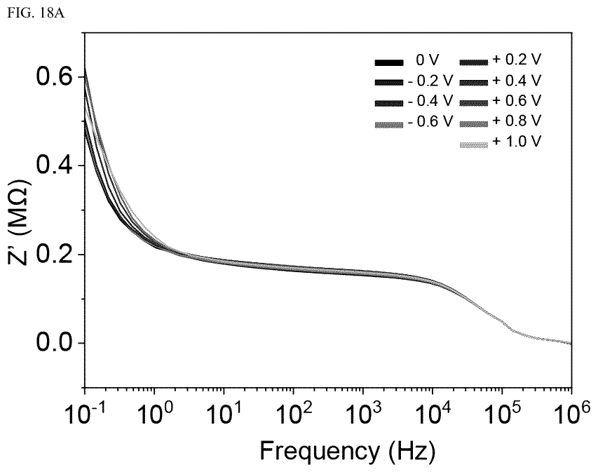

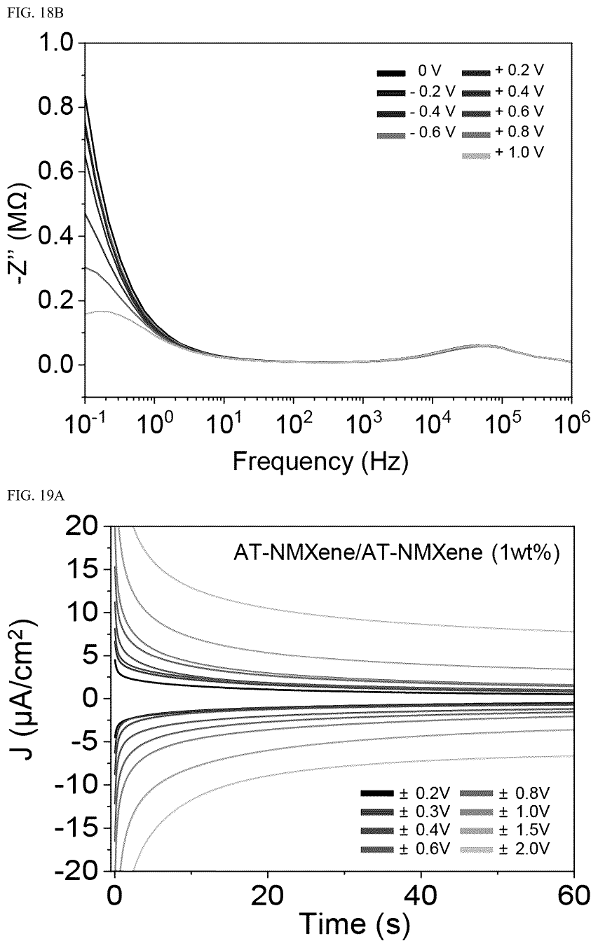

X-ray photoelectron spectroscopy analysis further confirmed the formation of additional mobile ions in both AT-NMXene and ES-PMXene, as shown in FIG. 17. The integrated area ratio of the N⁻ peak derived from [TFSI]⁻ anions in the X-ray photoelectron spectroscopy spectra increased when 1 wt % NMXene was incorporated into AT. In addition, the integrated area ratio of the N⁺ peak derived from [EMIM]⁺ cations increased when 1 wt % PMXene was incorporated into ES. These results indicate an increase in effective mobile ions in both samples, since the peak area in X-ray photoelectron spectroscopy is proportional to the concentration of the corresponding element.

Based on the diffusion ordered spectroscopy and X-ray photoelectron spectroscopy results, it is considered that the cationic polymer backbone preferentially associates with NMXene having a negatively charged surface, thereby releasing mobile anions from the backbone. The release of mobile anions enhances the ionic conductivity of the sample. In the case of AT-NMXene, the polymer backbone containing fixed cations interacts with NMXene, resulting in the release of mobile anions into the system and enhancement of ionic conductivity. In the case of ES-PMXene, the polymer backbone containing fixed anions interacts with PMXene, thereby increasing the ionic conductivity of the sample.

### Experimental Example: Ionic Performance of Heterojunction ES-PMXene/AT-NMXene Diodes

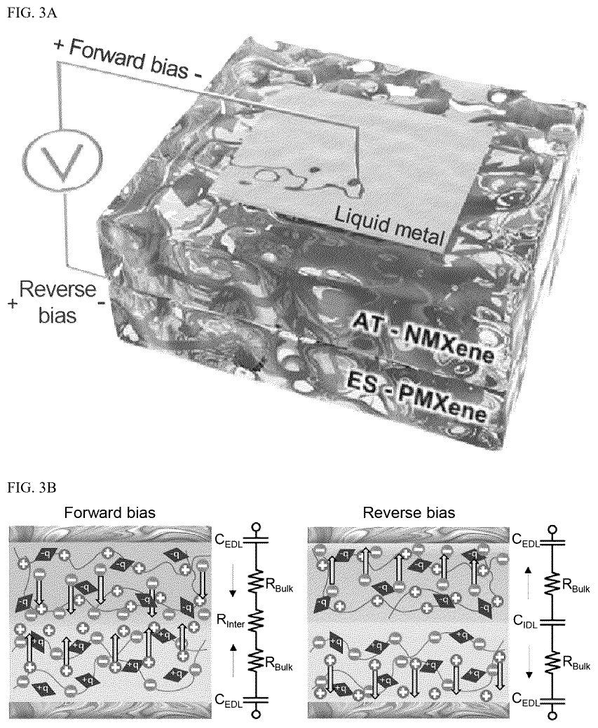

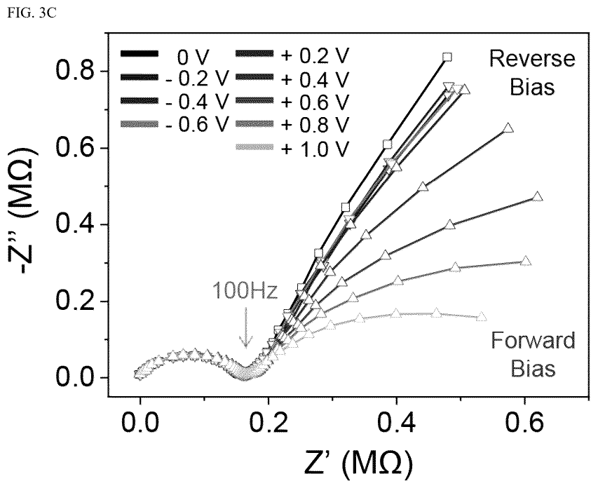

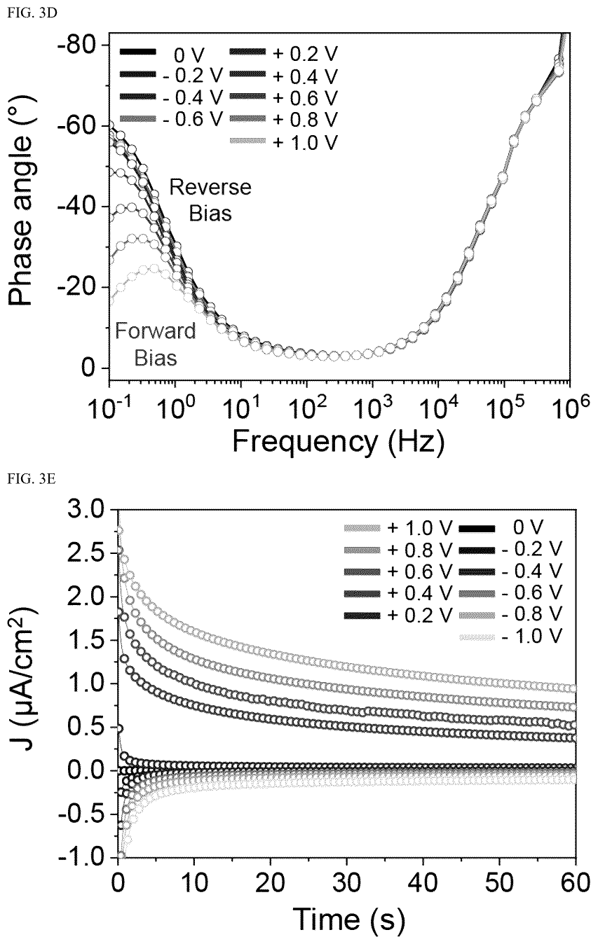

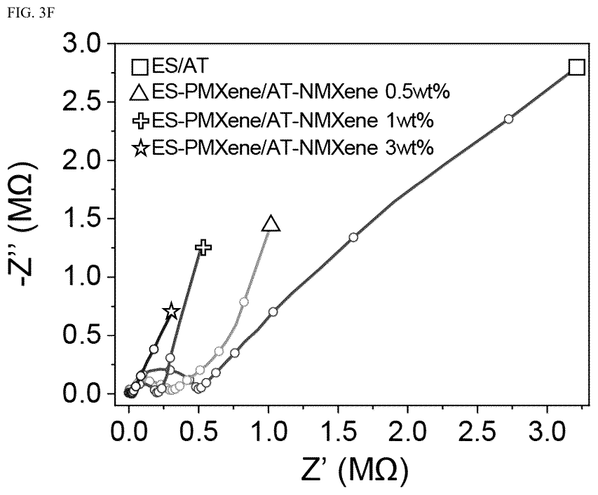

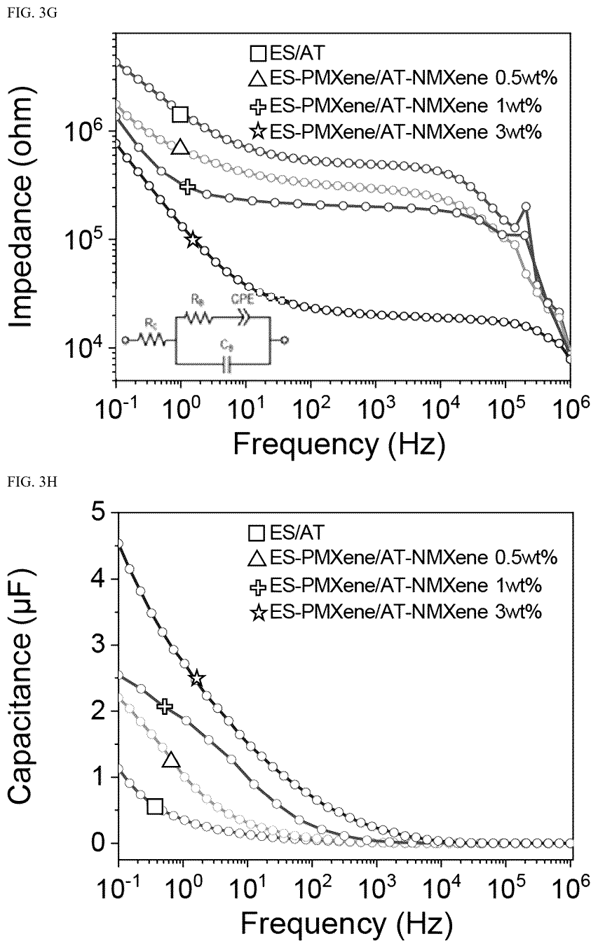

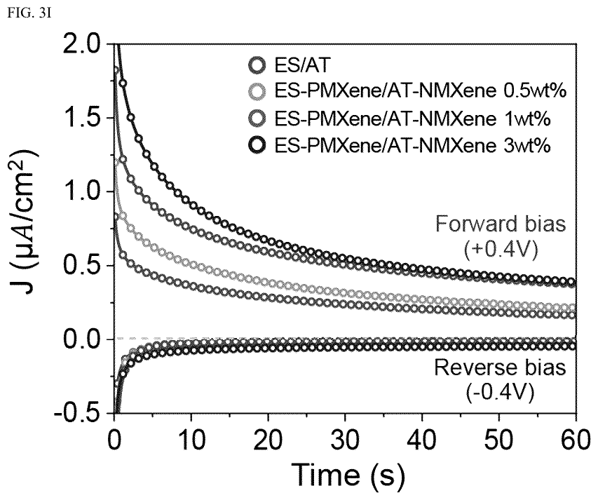

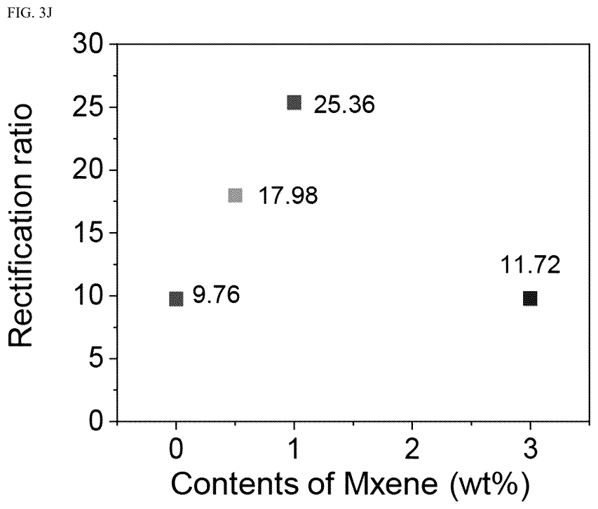

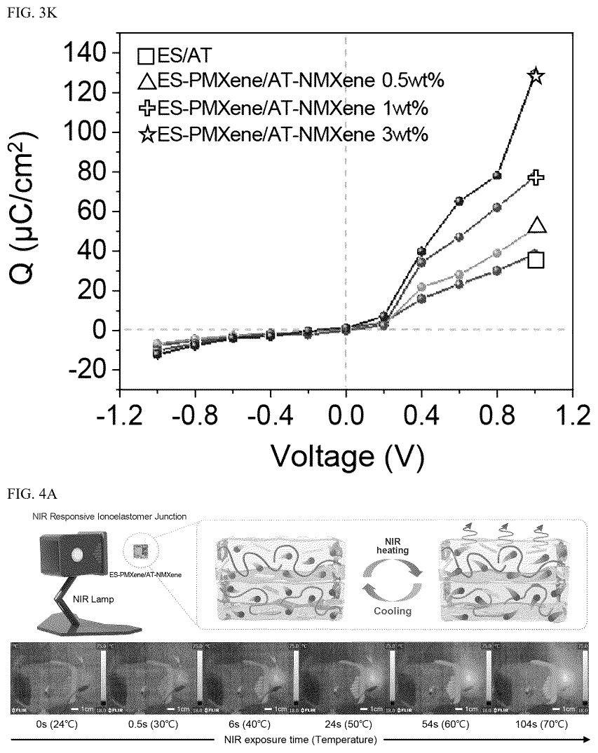

When ES-PMXene and AT-NMXene were physically stacked, a junction diode was formed with top and bottom electrodes, as schematically illustrated in FIG. 3A. At the interface of the ES-PMXene/AT-NMXene junction, [EMIM]⁺ cations from ES-PMXene diffused toward AT-NMXene, while [TFSI]⁻ anions from AT-NMXene diffused toward ES-PMXene through an entropy-driven process. As a result of this diffusion, cross-linked [SPA]⁻ anions remained in ES-PMXene and [AEBI] cations remained in AT-NMXene. In addition, long-range motion of both [SPA]⁻ anions and [AEBI] cations was restricted at the junction. Under these conditions, a characteristic ionic double layer was formed at the junction, analogous to a depletion layer in an electronic p-n semiconductor junction, as illustrated in FIG. 3B. An interfacial electric field was formed from AT-NMXene toward ES-PMXene at the ionic double layer, resulting in a drift current of mobile ions.

MXene is considered to enhance the effective potential associated with ionic double layer formation and to stabilize the interfacial depletion region by facilitating ion-dipole interactions between fixed ionic species and MXene surfaces, while a low MXene content of less than 1 wt % minimizes direct screening effects. When a forward bias was applied to the ES-PMXene/AT-NMXene junction diode, mobile [EMIM]⁺ cations in ES-PMXene moved toward the AT-NMXene interface, while mobile [TFSI]⁻ anions in AT-NMXene moved toward the ES-PMXene interface. As a result, the ionic double layer at the interface was disrupted, thereby allowing current flow across the junction. Conversely, when a reverse bias was applied, cations in ES-PMXene moved away from the junction interface toward the electrode, and anions in AT-NMXene also moved away from the junction, resulting in reconstruction of the ionic double layer at the interface. Under these conditions, current flow was substantially limited, and the diode exhibited capacitive behavior.

This operational mechanism is similar to asymmetric, field-induced electric double layer formation typically observed in single-ion-conductor-gated transistors. In such systems, depletion-like behavior arises from a capacitive imbalance between the electric double layer and a thicker depletion layer formed by immobilized counterions. Under an applied field, one ionic species is mobile while the opposite charge is covalently tethered to a polymer backbone. Due to the relatively low density of immobile backbone charges, charge compensation requires a broader depletion region, resulting in an effectively thicker electric double layer and asymmetric carrier accumulation. In the MXene-based ionic diode described herein, the ionic double layer is formed at the interface between polycationic and polyanionic ionoelastomers containing fixed ionic species through diffusion of mobile ions. Under an applied bias, the ionic double layer is dynamically formed and relaxed, reflecting reversible redistribution of ions across the junction. The rectifying behavior originates from this interfacial process, in which spatial redistribution of ions dynamically modulates the junction potential, thereby enabling operation as an ionic diode.

The impedance behavior of the ES-PMXene/AT-NMXene heterojunction under forward and reverse biases was examined under a direct current bias using electrochemical impedance spectroscopy, and the results are shown in FIGS. 3C and 3D. Nyquist plots in FIG. 3C were obtained as a function of forward and reverse bias by measuring real impedance and imaginary impedance values over a frequency range from 100 mHz to 1 MHz. Total impedance in the low-frequency region below 100 Hz decreased under forward bias due to a substantial reduction in imaginary impedance, whereas total impedance showed minimal variation under reverse bias, as shown in FIG. 3C. These results indicate that interfacial resistance at the ES-PMXene/AT-NMXene junction decreased under forward bias, thereby promoting transport of mobile ions toward the junction interface. In addition, the reduction in imaginary impedance under forward bias reflects a decrease in capacitance-related impedance, consistent with disruption of the ionic double layer.

Bode plots obtained as a function of forward and reverse bias are shown in FIG. 3D. In the low-frequency region below 100 Hz, a decrease in imaginary impedance under forward bias resulted in a reduction in phase angle, corresponding to breakdown of the ionic double layer. The current density of the ES-PMXene/AT-NMXene heterojunction containing 1 wt % MXene increased significantly under forward bias and decreased substantially under reverse bias, thereby exhibiting characteristic ionic rectification behavior, as shown in FIG. 3E. No rectification behavior was observed in homojunction configurations, as shown in FIG. 19.

The ionic properties of the ES-PMXene/AT-NMXene heterojunction were further examined as a function of the amounts of PMXene and NMXene incorporated into ES and AT, respectively, and the results are shown in FIGS. 3F, 3G, and 3H. The bulk resistance of the junction diode decreased with increasing MXene content from 0.499 MΩ at 0 wt % to 0.305 MΩ at 0.5 wt %, 0.204 MΩ at 1 wt %, and 0.020 MΩ at 3 wt %, as evidenced by the Nyquist plots in FIG. 3F. In addition, low-frequency behavior below 100 Hz indicated that resistance of the diffusion layer was reduced by MXene incorporation. Bode impedance plots in FIG. 3G show that impedance in the low-frequency region decreased with increasing MXene content due to enhanced ion mobility. Enhanced ion mobility was further supported by increased capacitance of the diode, particularly at frequencies below 1 kHz, as shown in FIG. 3H.

Consistent with the impedance and capacitance results, the current density of the heterojunction diode increased substantially with increasing MXene content under forward bias, as shown in FIG. 3I. Charge density (Q) was calculated by integrating current density (J) over time (t). Under a forward bias of 0.4 V, charge densities of approximately 16.23 μC cm⁻² at 0 wt %, 22.11 μC cm⁻² at 0.5 wt %, 34.51 μC cm⁻² at 1 wt %, and 44.06 μC cm⁻² at 3 wt % MXene were obtained. Under reverse bias, current density showed minimal variation with MXene content, yielding charge densities of approximately 1.66 μC cm⁻² at 0 wt %, 1.23 μC cm⁻² at 0.5 wt %, 1.36 μC cm⁻² at 1 wt %, and 4.9 μC cm⁻² at 3 wt %.

The rectification ratio was defined as the ratio of charge density under forward bias to charge density under reverse bias, expressed as Qf/Qr. Rectification ratios obtained at 0.4 V forward bias and −0.4 V reverse bias as a function of MXene content are shown in FIG. 3J. The rectification ratio of a diode without MXene was approximately 9.76, which increased to approximately 17.98 with 0.5 wt % MXene and further increased to approximately 25.36 with 1 wt % MXene. When 3 wt % MXene was incorporated, the rectification ratio decreased to approximately 11.72.

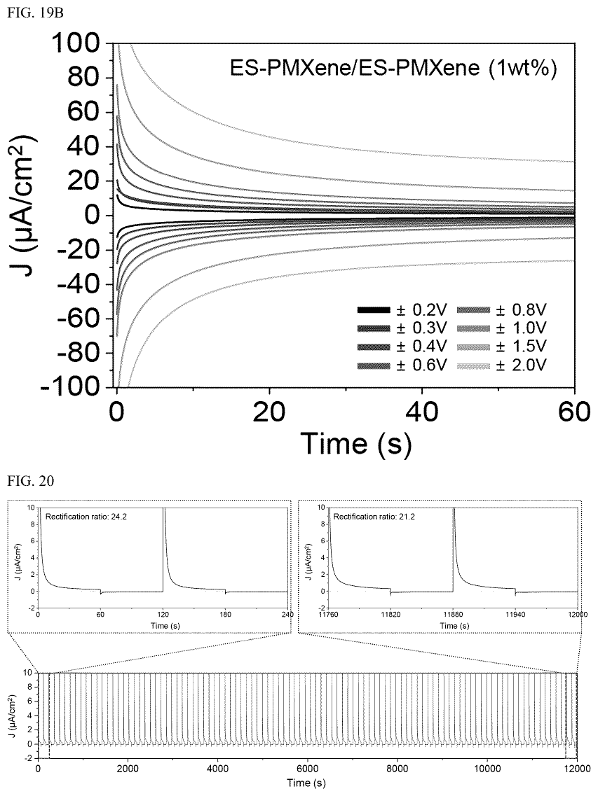

Q-V curves of heterojunction diodes with different MXene contents were obtained as a function of applied voltage, as shown in FIG. 3K. As the amount of charged MXene increased from 0 to 3 wt %, current density under forward bias increased due to resistive characteristics of the diode and increased electric double layer capacitance, which enabled greater current flow. Under reverse bias, formation of the ionic double layer caused the diode to behave in a capacitive manner, resulting in current density that was largely insensitive to MXene content. At a high MXene content of 3 wt %, the rectification ratio decreased primarily due to increased integrated current density under reverse bias, which is attributed to electrical leakage associated with excessive MXene content. An optimal MXene content of approximately 1 wt % relative to the ionoelastomer was identified, and the ES-PMXene/AT-NMXene heterojunction diode containing 1 wt % MXene operated stably over 100 cycles of forward and reverse bias with only a minor change in rectification ratio of approximately 13%, as shown in FIG. 20.

The ES-PMXene/AT-NMXene heterojunction diode exhibited mechanical stretchability, as shown in FIG. 21. Upon stretching, bulk resistance of the diode decreased due to a reduction in diode thickness. It is noted that variation in bulk resistance upon stretching differed from that observed in conventional ionoelastomer diodes, which is attributed to alignment of MXene flakes within the diode during stretching. Nevertheless, the ES-PMXene/AT-NMXene heterojunction diode is considered suitable for stretchable and wearable applications.

### Experimental Example: Modulation of ES-PMXene/AT-NMXene Diodes With NIR

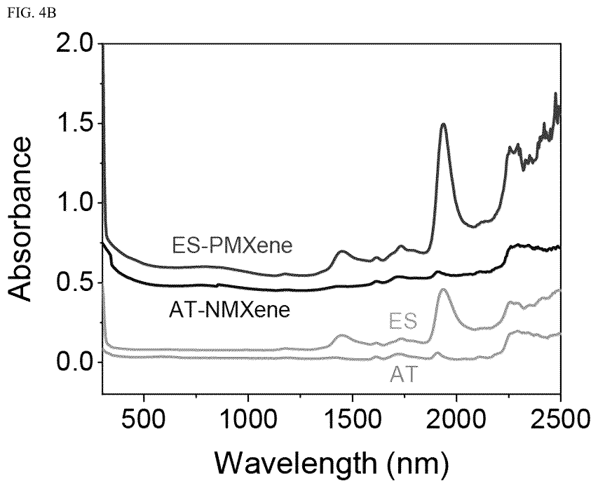

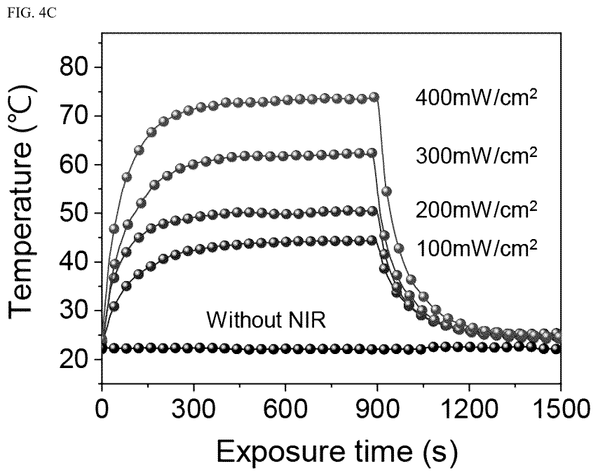

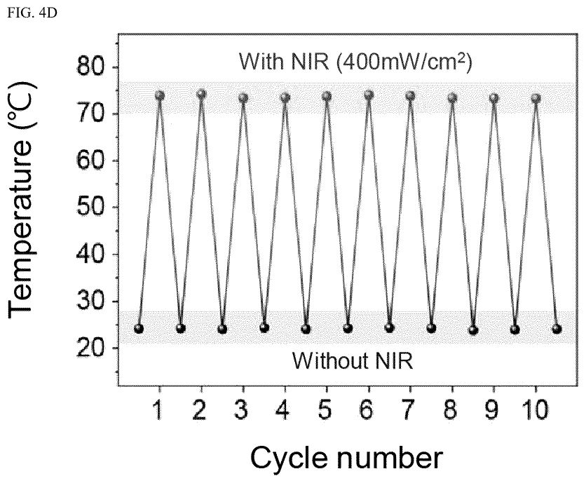

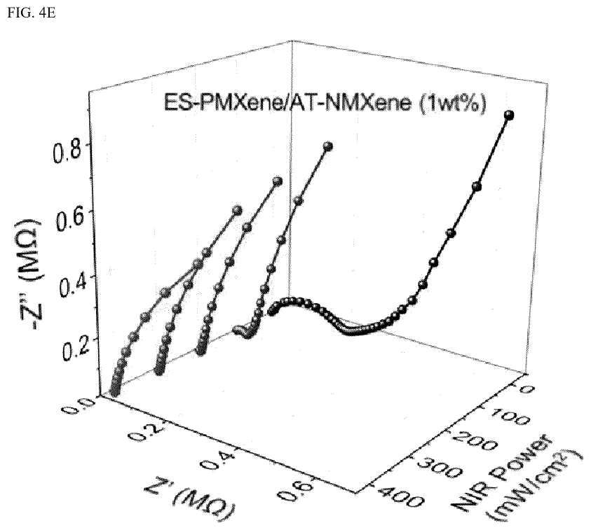

Upon exposure of an ES-PMXene/AT-NMXene junction diode to near-infrared light having a wavelength of 945 nm, a noticeable increase in diode temperature was observed due to the NIR photothermal conversion effect of MXene, as illustrated in FIG. 4A. The temperature variation of the diode as a function of NIR exposure time was monitored using a forward looking infrared camera. When an ES-PMXene/AT-NMXene junction diode containing 1 wt % MXene was exposed to NIR light at a power density of 400 mW cm⁻², the temperature of the diode increased over time from room temperature of approximately 24 °C to about 30, 40, 50, 60, and 70 °C after 0.5 s, 6 s, 24 s, 54 s, and 104 s, respectively, as shown in the series of photographs in FIG. 4A. The photothermal effect originating from MXene was further confirmed by ultraviolet-visible-near-infrared spectroscopy, in which composites containing PMXene or NMXene exhibited higher light absorption over a broad wavelength range in the NIR region compared to an ionoelastomer without MXene, as shown in FIG. 4B.

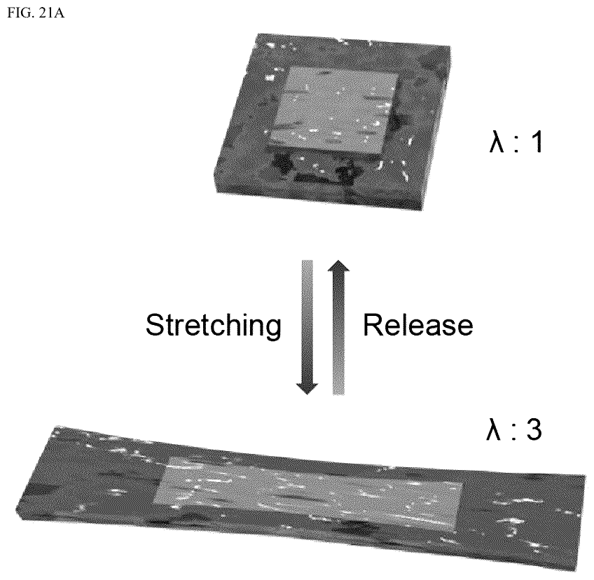

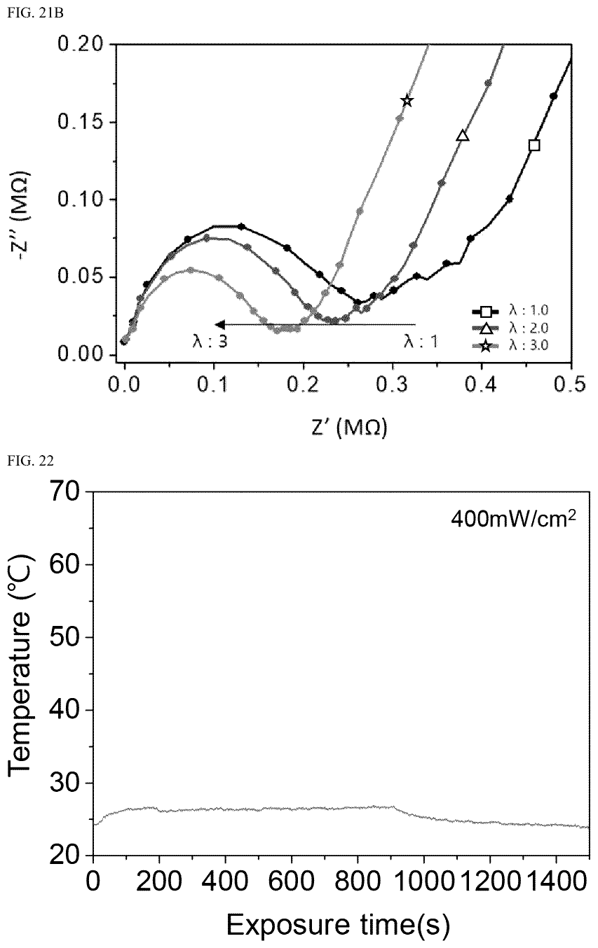

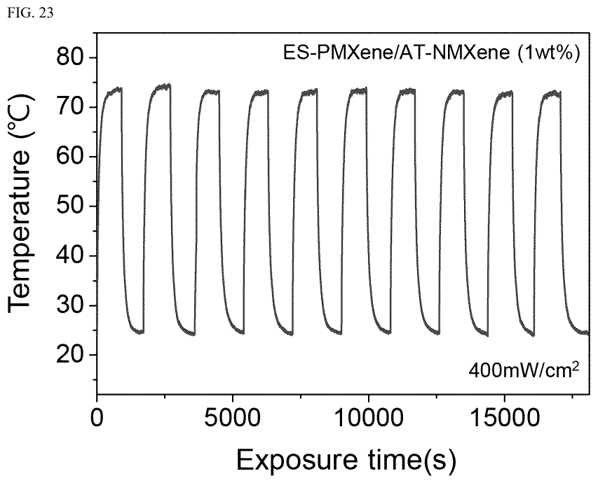

The temperature variation of the ES-PMXene/AT-NMXene junction diode containing 1 wt % MXene was further examined as a function of NIR power, and the results are shown in FIG. 4C. The saturation temperature of the diode after 400 s of NIR exposure increased to approximately 44.3, 50.7, 62.3, and 73.5 °C at NIR power densities of 100, 200, 300, and 400 mW cm⁻², respectively. In addition, the photothermal heating rate, defined as the slope obtained by fitting the temperature variation curve over one minute of NIR exposure in units of K min⁻¹, was evaluated as a function of NIR power. Heating rates of approximately 9.84, 16.22, 22.07, and 30.28 K min⁻¹ were obtained at NIR power densities of 100, 200, 300, and 400 mW cm⁻², respectively. In contrast, an ES/AT bilayer without MXene exhibited almost no temperature change upon NIR exposure, as shown in FIG. 22. When the NIR light was turned off, the diode temperature decreased rapidly, as shown in FIG. 4C. Reversible heating and cooling of the heterojunction diode containing 1 wt % MXene was confirmed over ten cycles by repeated NIR ON and OFF operations, as shown in FIGS. 4D and 23.

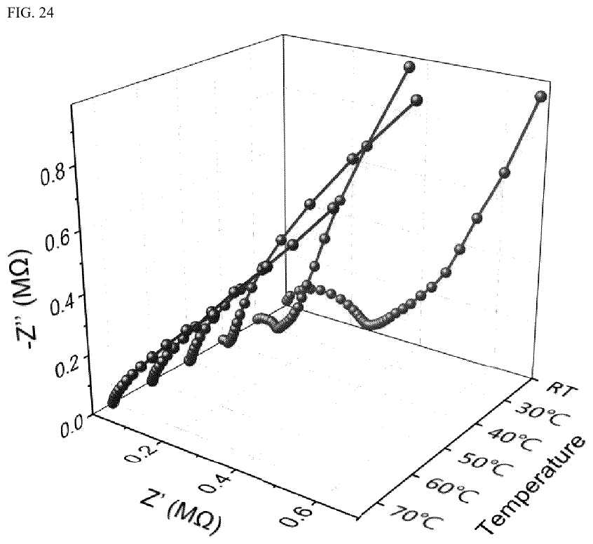

The ionic properties of the ES-PMXene/AT-NMXene junction diode containing 1 wt % MXene were also evaluated as functions of NIR exposure, and Nyquist plots of the diode under different NIR power conditions are shown in FIG. 4E. The bulk resistance of the diode decreased from approximately 238.4 kΩ to 36.2 kΩ, 8.2 kΩ, 5.4 kΩ, and 2.3 kΩ at NIR power densities of 0, 100, 200, 300, and 400 mW cm⁻², respectively, due to thermally enhanced ionic conductivity, as shown in FIG. 24. The rectification ratio of the ES-PMXene/AT-NMXene junction diode increased with NIR exposure, as shown in FIG. 4F. A relative rectification ratio, defined as the rectification ratio of an ES/AT diode without MXene divided by that of a diode containing MXene, was approximately 2.11 when charged MXene at 1 wt % was incorporated. Upon NIR exposure, the relative rectification ratio further increased to approximately 2.45, 2.67, 3.11, and 3.13 at NIR power densities of 100, 200, 300, and 400 mW cm⁻², respectively. In contrast, the rectification ratio of a diode without MXene showed minimal variation with NIR exposure, as shown in FIG. 4F.

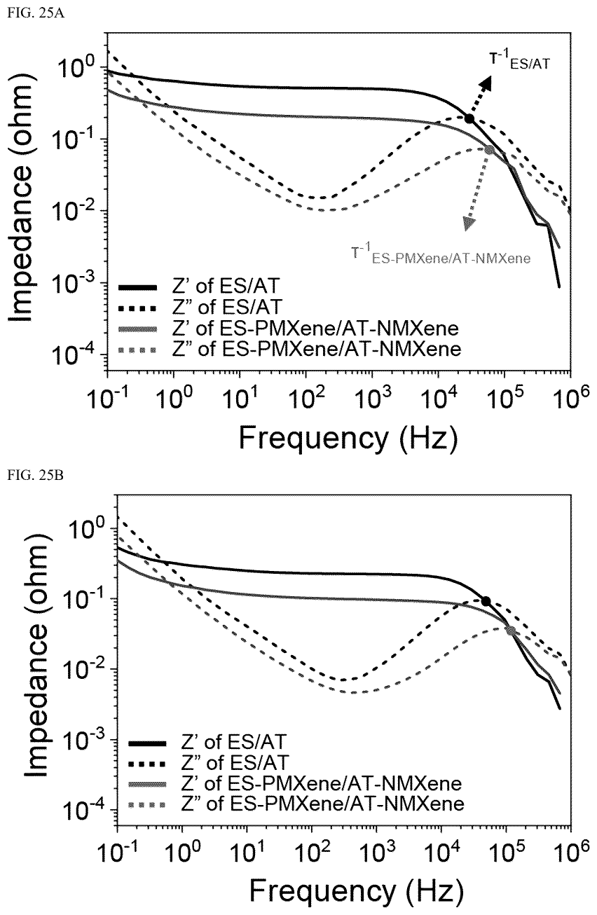

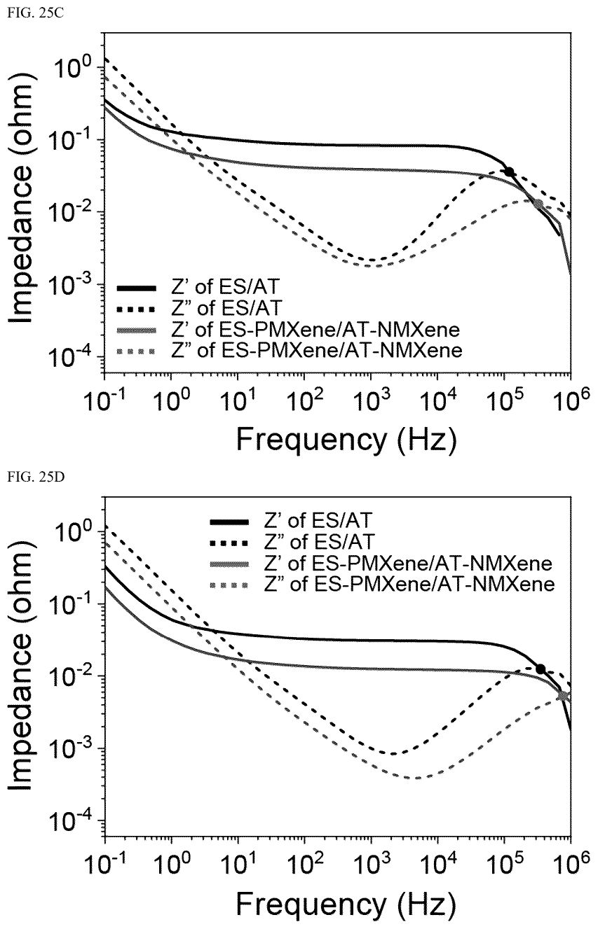

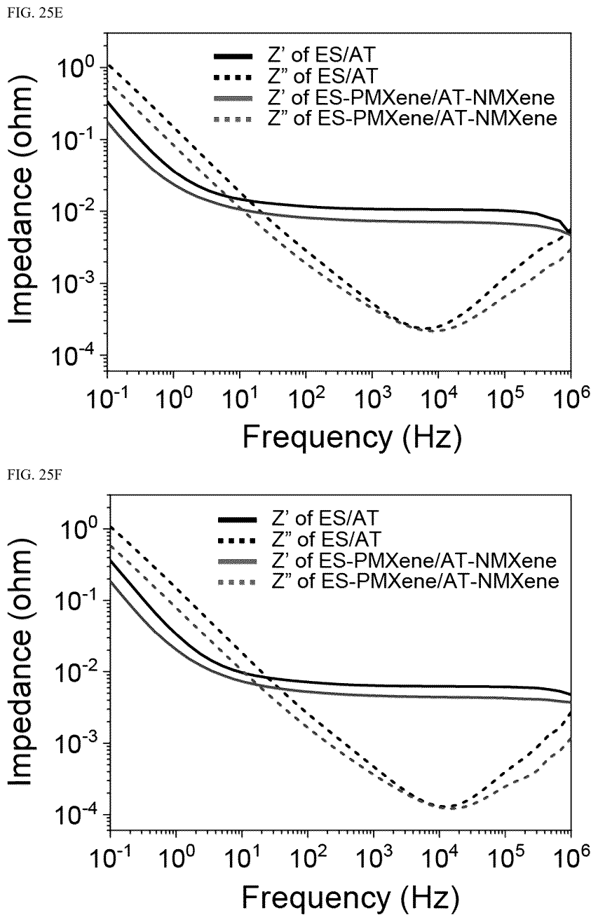

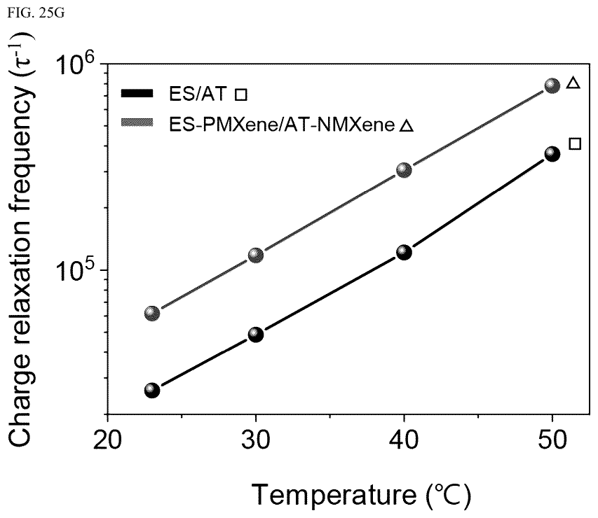

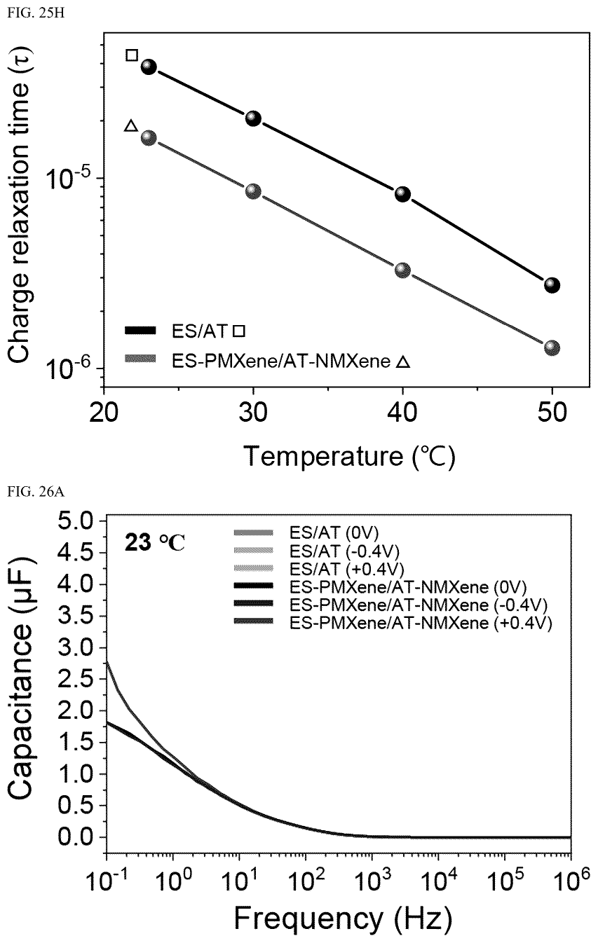

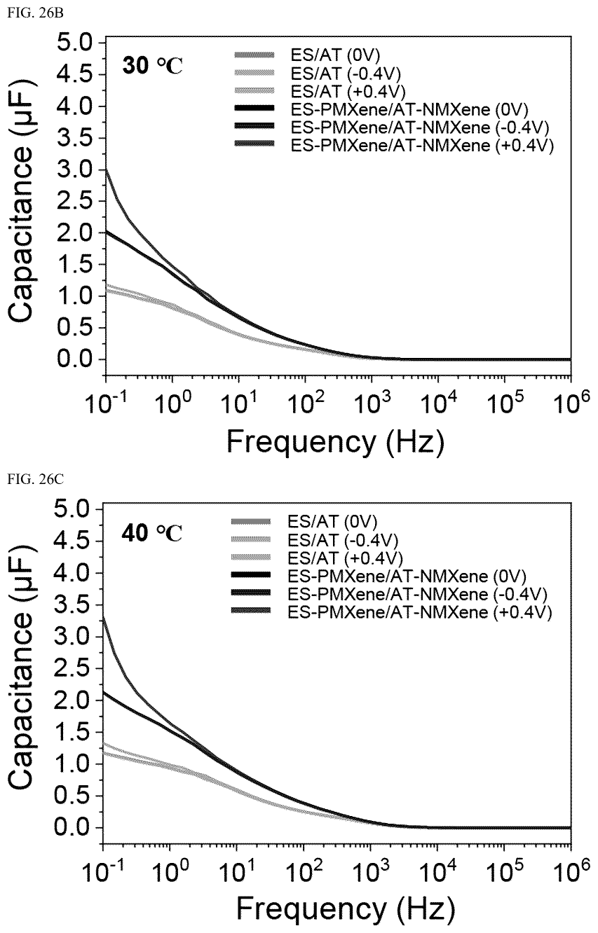

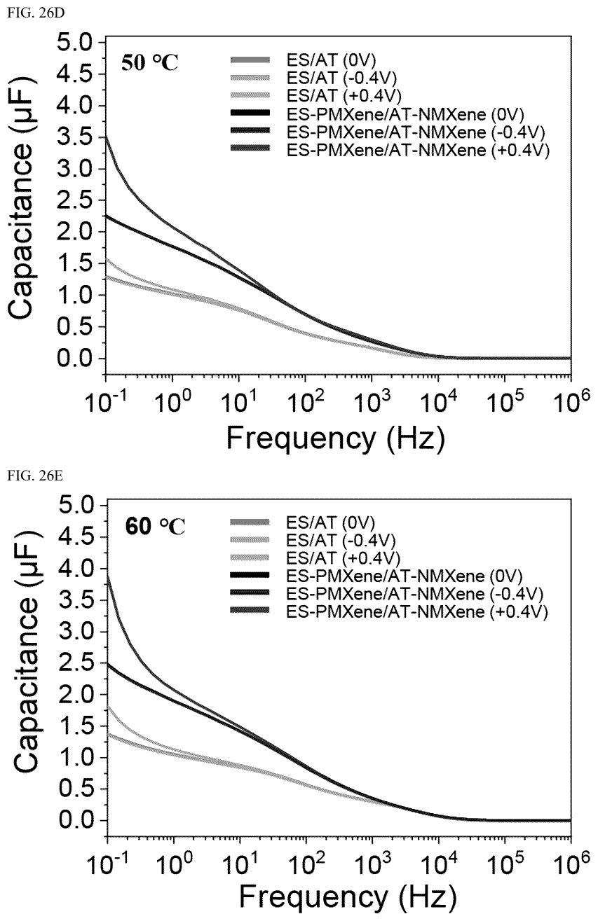

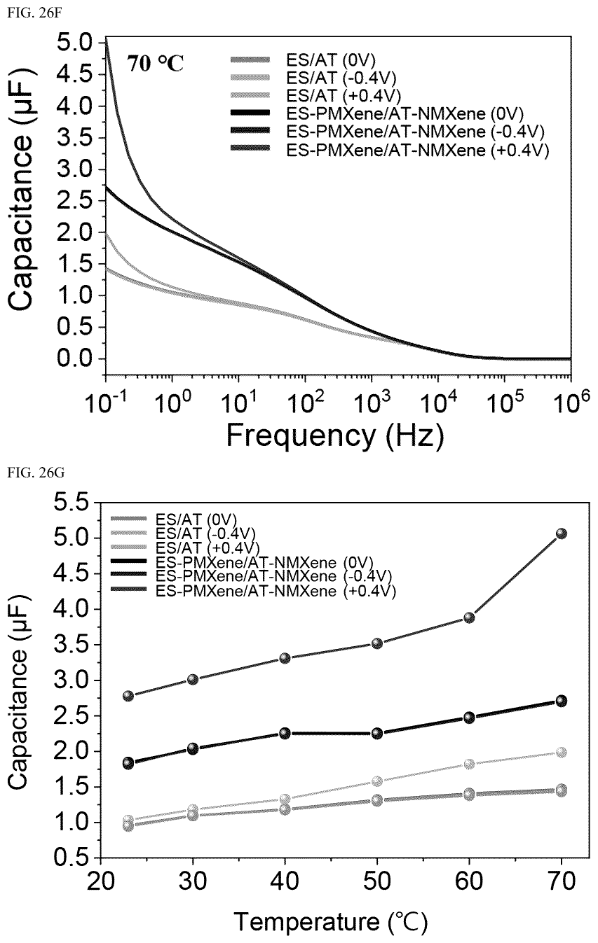

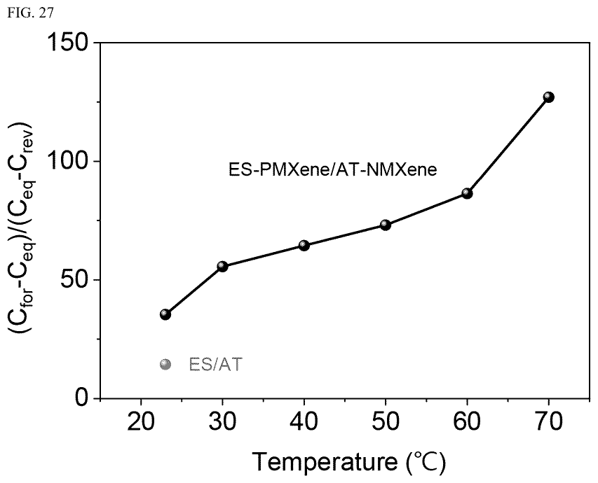

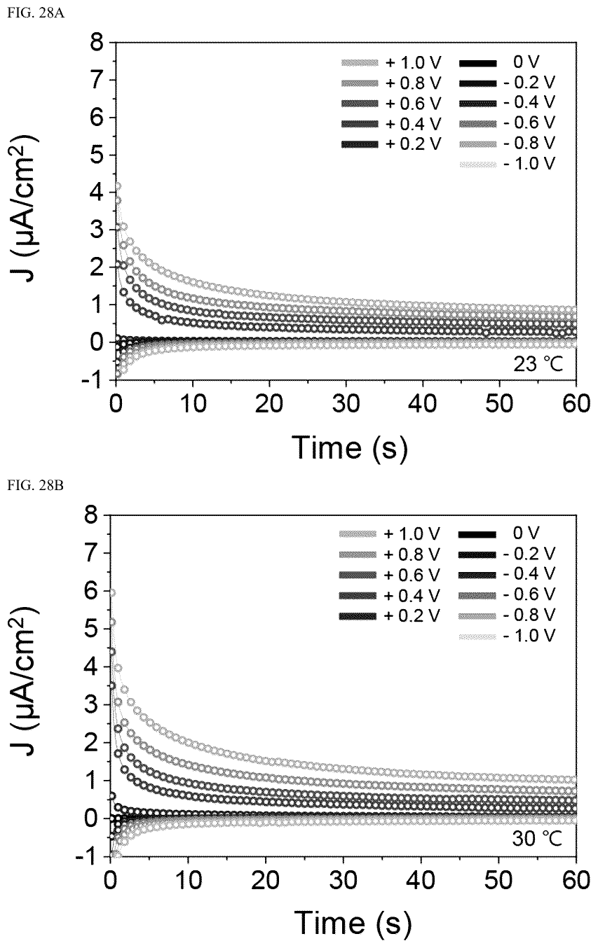

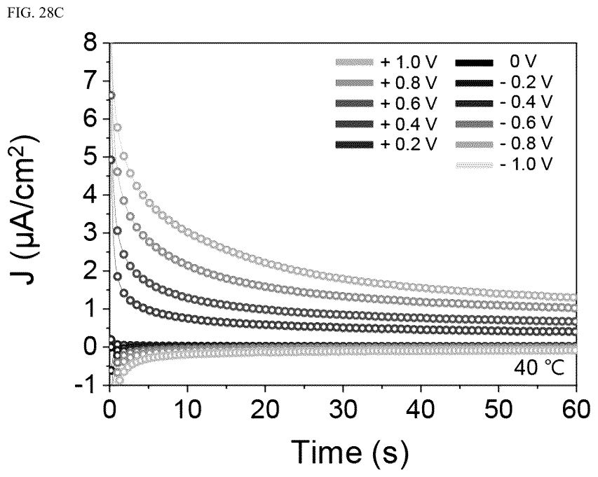

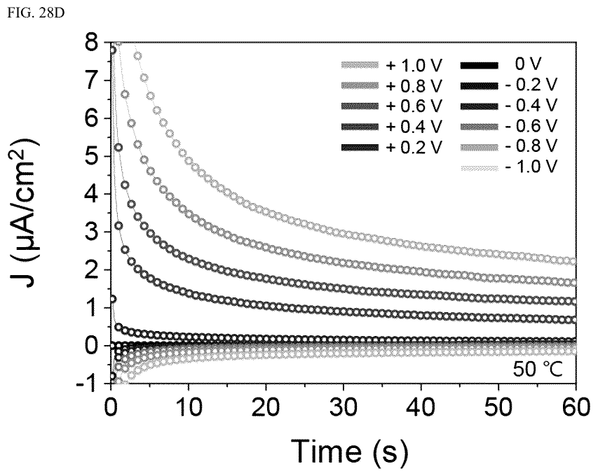

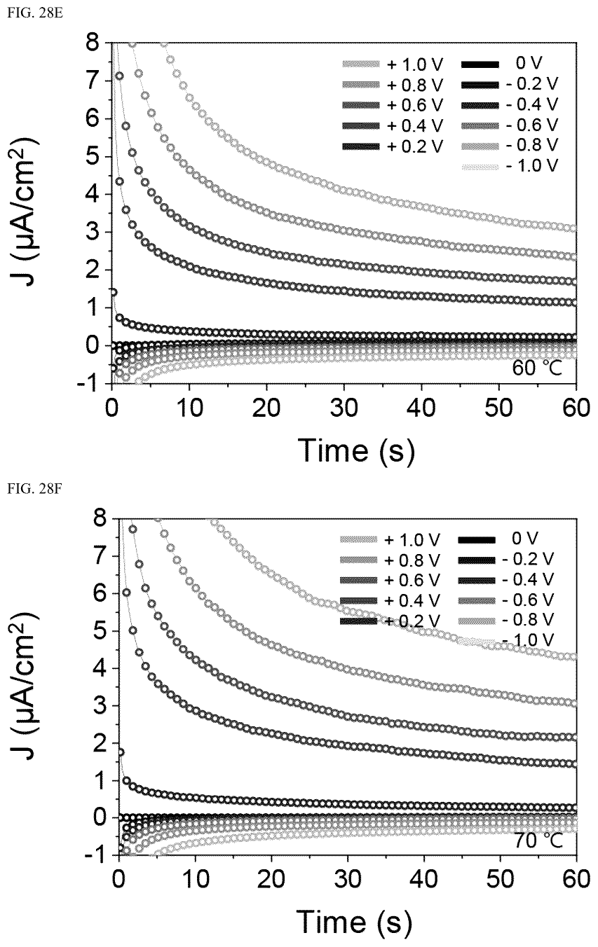

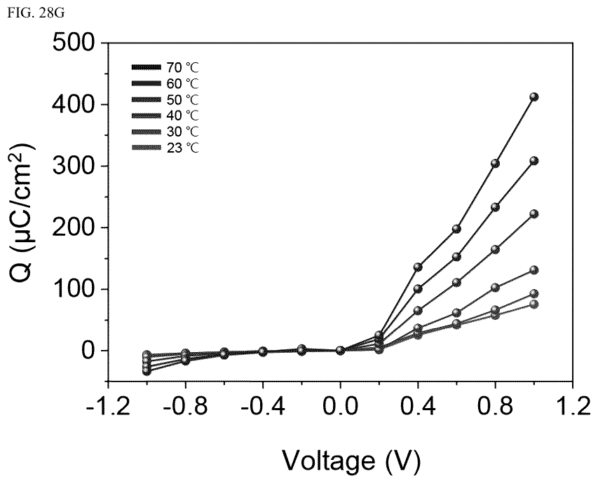

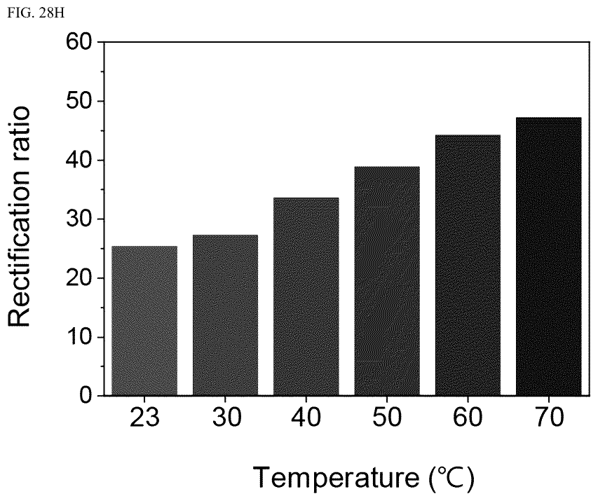

In addition, the charge density plot of the diode under NIR exposure at 400 mW cm⁻² as a function of applied forward and reverse voltage, as shown in FIG. 4G, exhibited enhanced rectification behavior compared to the diode without NIR exposure. The rectification ratio observed in the ionic diode under NIR exposure increased with increasing temperature, which may be attributed to enhanced ionic conductivity. As ionic conductivity increases, the charge relaxation time (τ=ϵ/σ=RC) decreases, resulting in faster response time and enabling more rapid charge transfer, as shown in FIG. 25. Furthermore, higher temperatures promote increased ion dissociation, leading to an increase in the effective number of mobile ions. This increase enhances the electric double layer capacitance, which contributes to increased current under forward bias, as shown in FIGS. 26 and 27. A quantitative analysis of current as a function of temperature further demonstrated clear temperature-dependent behavior of the heterojunction ionic diode. Specifically, forward bias current increased with rising temperature, while reverse bias current exhibited negligible change, thereby resulting in an enhanced rectification ratio, as shown in FIG. 28. Accordingly, reversible temperature control of the heterojunction diode via the NIR photothermal effect enables the realization of an NIR-responsive, switchable ionic logic gate, as described below.

### Experimental Example: NIR-Responsive Switchable Ionic Logic Gate

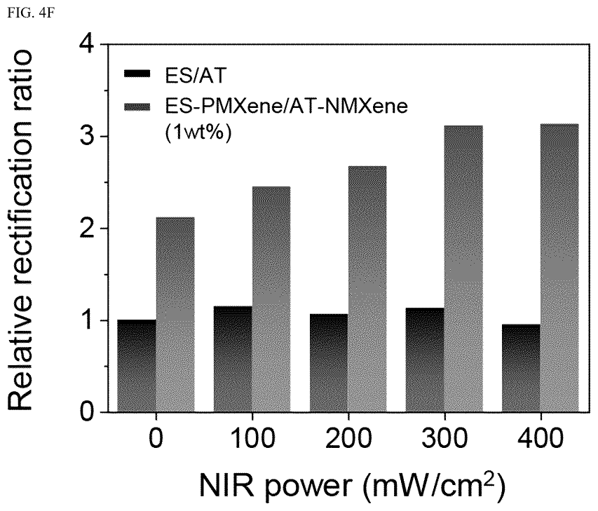

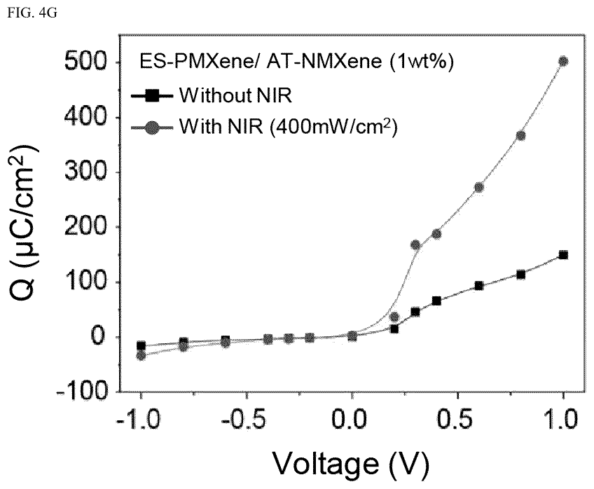

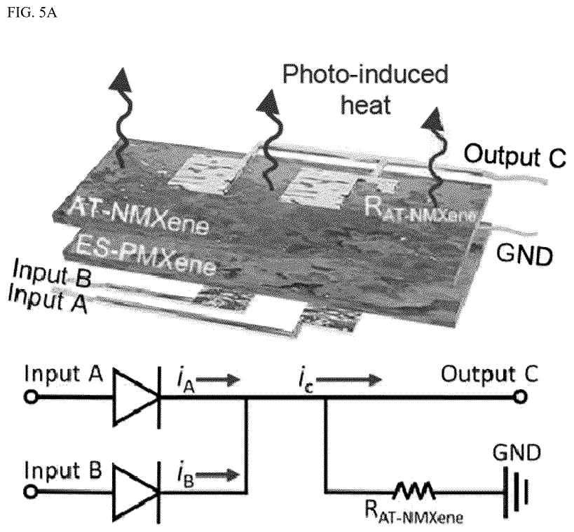

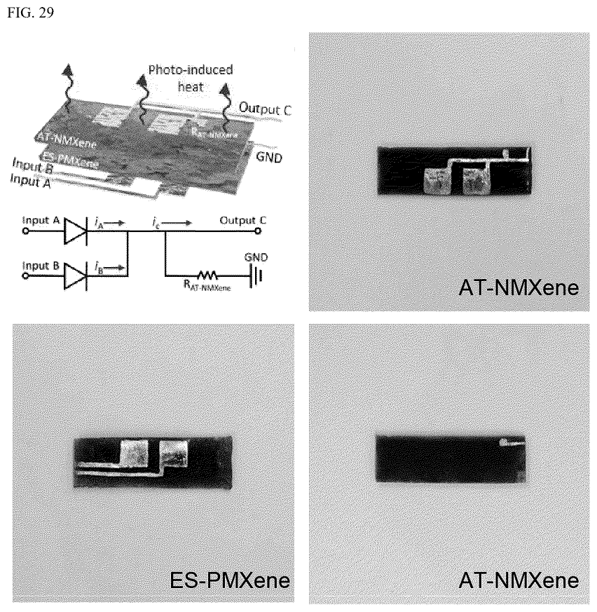

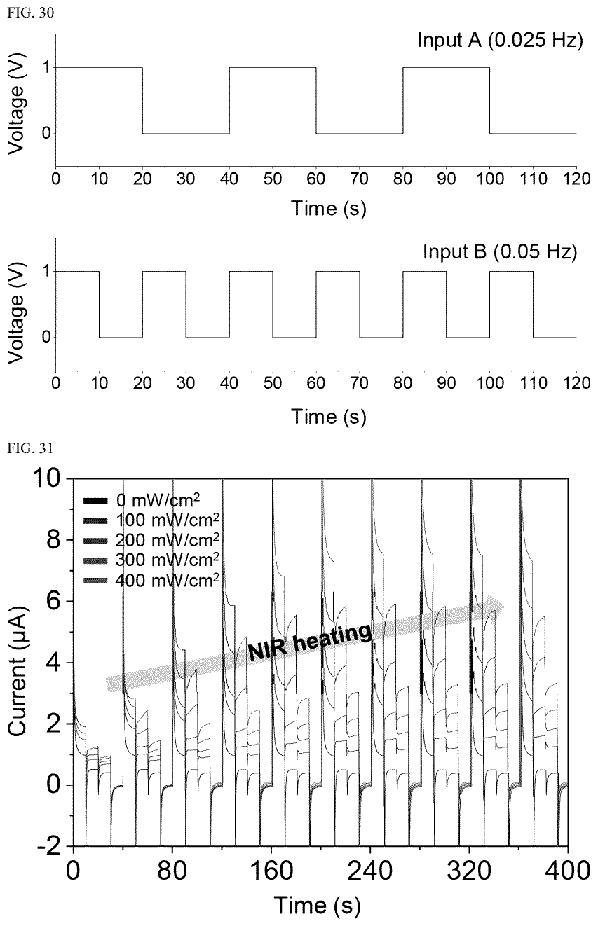

An NIR-responsive switchable ionic logic gate was fabricated using an ES-PMXene/AT-NMXene junction containing 1 wt % MXene in combination with stencil-printed liquid metal eutectic gallium-indium interconnectors, and the results are shown in FIGS. 5A to 5G. An ionic AND logic gate was configured to include two vertically stacked ionic diodes of an EGaIn/ES-PMXene/AT-NMXene heterojunction/EGaIn structure and a resistor interconnected with each other, as schematically illustrated in FIG. 5A. In the fabricated ionic AND logic gate, EGaIn electrodes having areas of 5 by 5 mm and 1.5 by 1.5 mm were used for the ionic diodes and the resistor, respectively, and an EGaIn interconnector having a width of 1 mm was employed. An equivalent circuit of the ionic logic gate including two inputs A and B and an output terminal C is shown in FIGS. 5A and 29. In an AND logic gate configuration, output current flows only when voltages at both input terminals A and B exceed a threshold input voltage, whereas in an OR logic gate configuration, output current flows when the voltage at either input A or input B exceeds the threshold voltage. Voltage signals were programmed as square waves at frequencies f_{A} of 0.025 Hz and f_{B} of 0.05 Hz for inputs A and B, respectively, as shown in FIG. 30. Four logic input states were generated by combining inputs A and B as (0,0), (0,1), (1,0), and (1,1) by varying the driving voltages applied to A and B. The logic gate initially operated as an AND gate, and upon exposure to NIR, transitioned from an AND gate to an OR gate due to photothermal heating. Upon cooling, the logic gate returned to operation as an AND gate, as illustrated in FIG. 5B.

An ionic AND logic gate based on output current was first evaluated. Output current values were measured when voltage biases were applied to inputs A and B, as shown in FIG. 5C. An input signal of +1 volt was defined as a logical “1”. The four logic input states were set as (1,1), (1,0), (0,1), and (0,0) corresponding to input A and input B. A measurement cycle of 40 s was performed as follows. Initially, inputs A and B were both turned on to form the (1,1) state for 10 s. Subsequently, input B was turned off while input A remained on to form the (1,0) state for the next 10 s. Then, input A was turned off and input B was turned on to form the (0,1) state for 10 s. Finally, both inputs A and B were turned off to form the (0,0) state for the final 10 s, thereby completing one cycle. When the output current resulting from both inputs A and B exceeded a threshold value, the output was defined as logical “1”. In addition, the logical “1” state of output C was defined when the output current exceeded an upper threshold current of 0.6 μA, and the logical “0” state was defined when the output current was lower than 0.6 μA. When a signal was applied to only one of inputs A or B, or when no signal was applied to either input, the output current did not exceed the threshold, resulting in an output value of “0”. Accordingly, the ionoelastomer diode operated as an AND gate, as shown in the left portion of FIG. 5C.

The output current of the logic gate was modulated by the photothermal effect of MXene, as shown in the middle portion of FIG. 5C. The output current of the logic gate increased with increasing NIR power for all input states except the final state in which both inputs A and B were turned off during a 40 second input cycle. When the logic gate was exposed to NIR at a power density of 400 mW cm⁻², the output current generated by input A or input B alone exceeded the output current threshold of 0.6 μA. Under these conditions, the input states (1,1), (1,0), and (0,1) were all defined as logical “1”, while the (0,0) state remained logical “0”, and thus the logic gate operated as an OR gate. The output current of the logic gate varied depending on NIR power and exposure time, as shown in FIG. 31. Upon cooling, the logic gate returned to AND gate operation, in which only the (1,1) state corresponded to logical “1” and the remaining three states corresponded to logical “0”, as shown in the right portion of FIG. 5C. As shown in FIG. 5D, nine consecutive AND gate operations and one OR gate operation were obtained over ten programming cycles without NIR exposure and with NIR exposure, respectively. An OR gate operation appeared consistently when NIR light was applied to the logic gate, as indicated by the pink shaded cycle in FIG. 5D. When the logic gate was cooled to room temperature after NIR irradiation was stopped, it again functioned as an AND gate. Additional sets of programming cycles were performed, each set including nine AND gate operations and one OR gate operation, thereby demonstrating reliable and reversible switching between AND and OR logic functions over extended operation time, as shown in FIG. 5D.

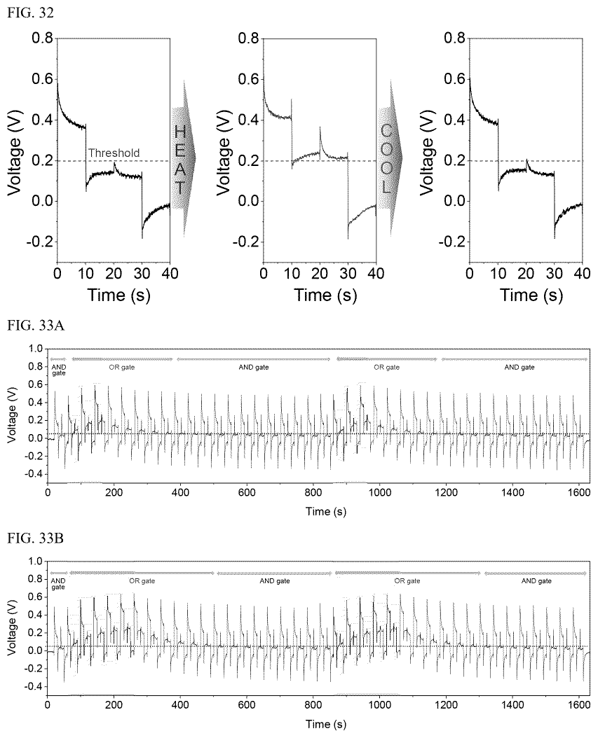

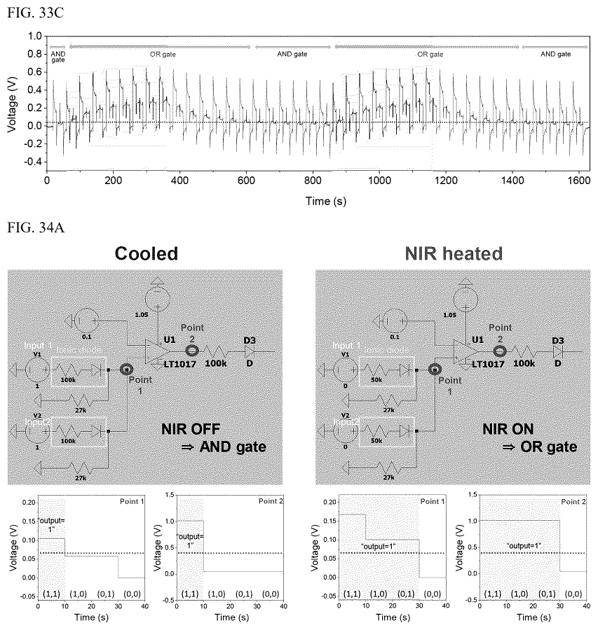

To further improve reliability, a resistor was incorporated into the output line of the NIR-responsive logic gate to convert output current signals into voltage signals, followed by amplification of the output voltage, as shown in FIGS. 5E and 32. The converted and amplified output voltages were measured using a data acquisition system, as shown in FIG. 5F. In voltage mode operation, the NIR-responsive logic gate functioned as an AND gate at room temperature, as shown in the left image of FIG. 32. Upon exposure to NIR at a power density of 400 mW cm⁻², OR gate behavior was obtained, in which the (1,1), (1,0), and (0,1) states corresponded to logical “1” and the (0,0) state corresponded to logical “0”, consistent with the current mode results, as shown in FIG. 5E and the middle image of FIG. 32. After cooling, the logic gate again operated as an AND gate, as shown in the right image of FIG. 32. Similar to current mode operation, additional sets of programming cycles were performed in voltage mode, and in each set, nine AND gate operations were followed by one OR gate operation under NIR exposure, as indicated by the pink shaded region in FIG. 5E. Accordingly, the logic gate was reversibly switchable between AND and OR logic functions without observable performance degradation over more than ten switching cycles. The number of consecutive OR gate operations was controlled by the NIR exposure time, as shown in FIG. 33.

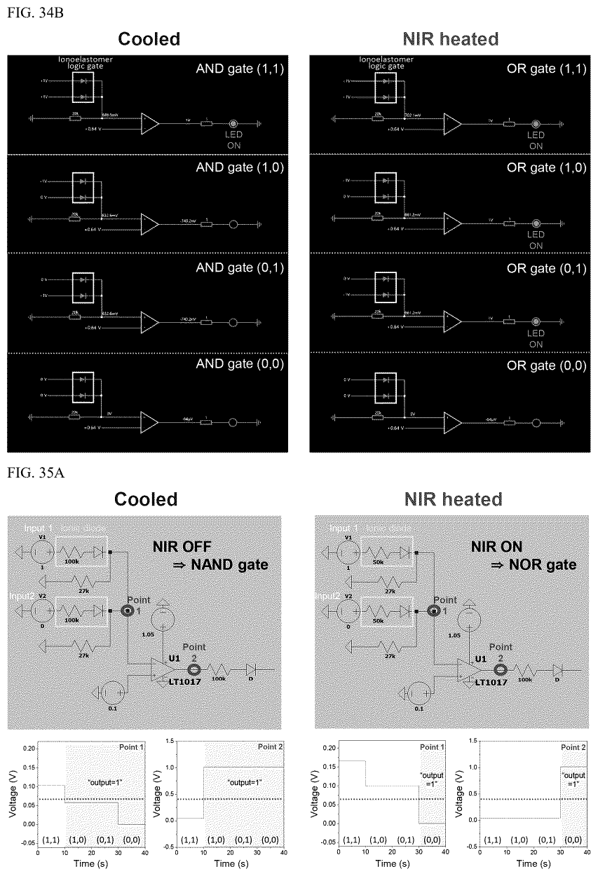

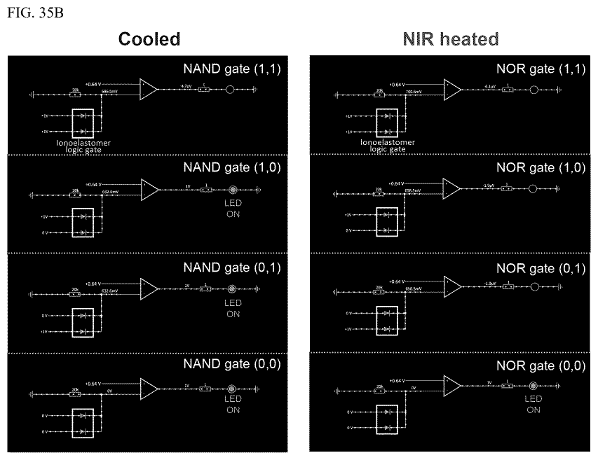

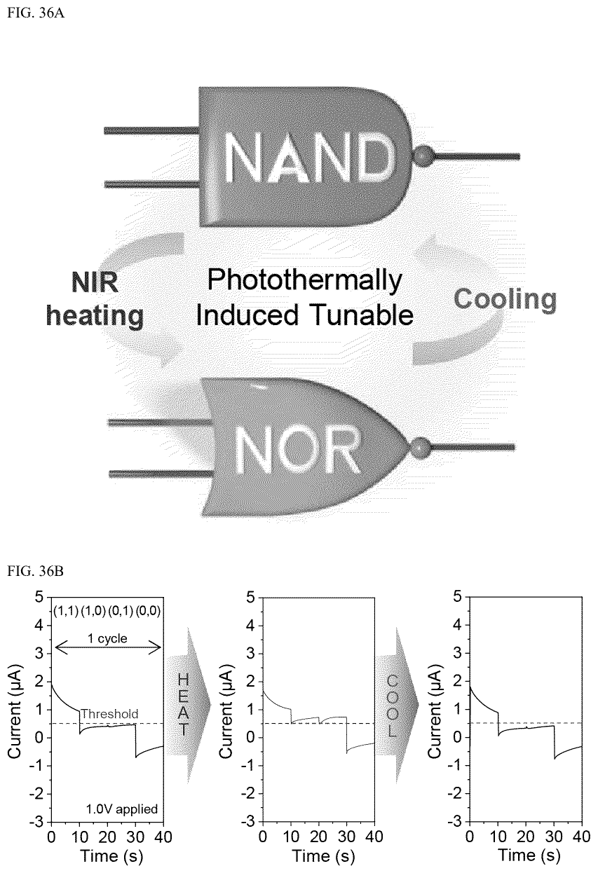

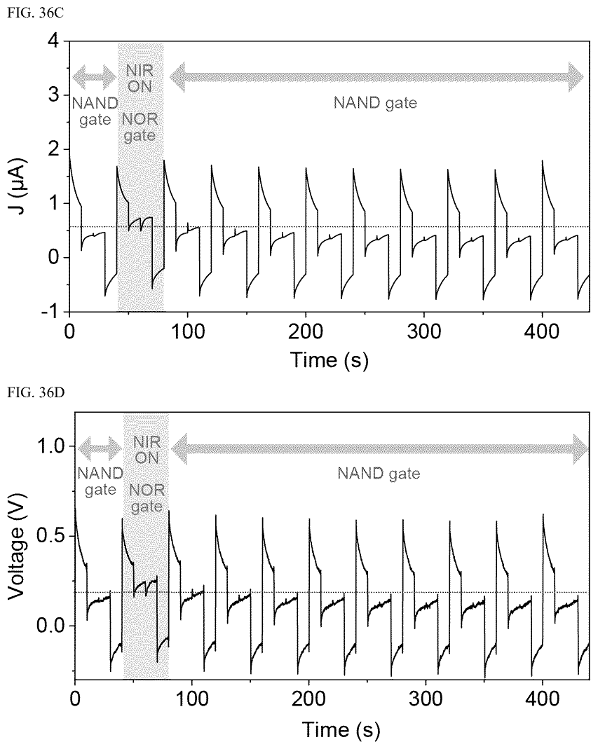

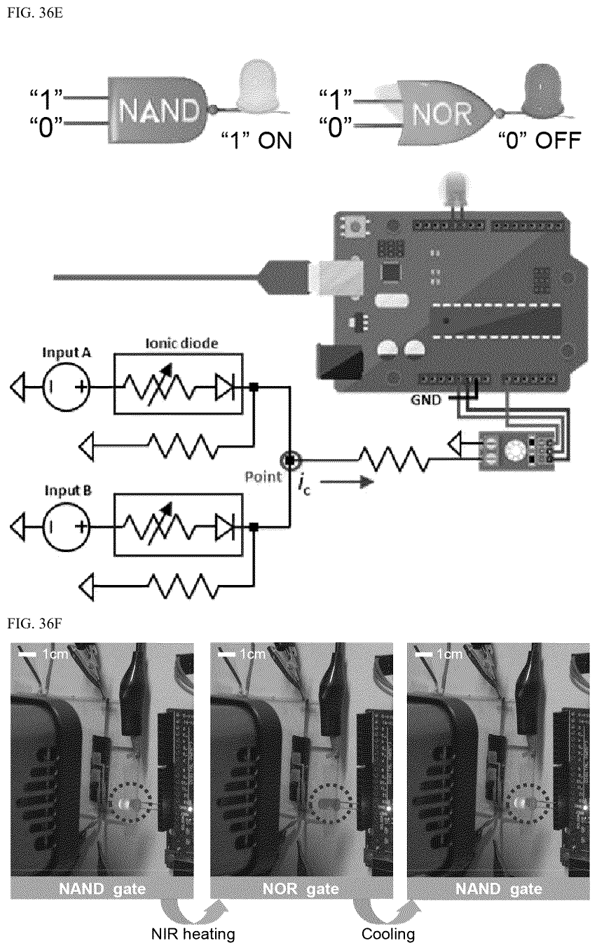

Switching between AND and OR logic functions using the NIR-responsive logic gate was further visualized by incorporating an Arduino and conventional light-emitting diodes into the logic gate circuit, as illustrated in FIG. 5F, and the results are shown in FIG. 5G. In this configuration, the light-emitting diode remained off when the logic gate operated as an AND gate at room temperature. When the logic gate transitioned to OR gate operation upon NIR exposure, the light-emitting diode was turned on. Reversible switching between AND and OR logic functions was further supported by equivalent circuit simulations performed using LT-SPICE and the Falstad program, as shown in FIG. 34. In addition, by modifying the circuit to connect the switchable logic gate from a noninverting input terminal to an inverting input terminal of an operational amplifier comparator, logic gate operation switching from NAND to NOR in response to NIR irradiation was also achievable, as shown in FIGS. 35 and 36. Furthermore, scalable fabrication of the ionic logic system may be achieved by combining the described approach with micropatterning technology to enable high-density integration of devices. The described switchable logic gates provide circuit design simplicity and flexibility by reducing the number of required components, thereby making them suitable for various low-energy consumption and low-cost multifunctional logic applications.

### Conclusion

An NIR-responsive ionic junction enabling switchable AND and OR logic gate operation was provided. An ionic junction diode was formed by vertically stacking p-type and n-type ionoelastomers mixed with positively charged MXene and negatively charged MXene, respectively, between top and bottom liquid metal electrodes. Preferential interactions between the ionoelastomers and MXene facilitated dissociation of mobile ions from both ionoelastomers, thereby enhancing current rectification of the diode. In addition, by utilizing the photothermal effects of PMXene and NMXene under NIR exposure, current rectification was further enhanced when the diode was irradiated with NIR. Controlled modulation of diode rectification through NIR exposure enabled the development of a switchable logic gate in which an AND gate or NAND gate was reliably and reversibly converted to an OR gate or NOR gate through NIR-induced heating and subsequent cooling cycles.

In summary, key advances achieved through this work include the following. First, enhanced operational stability was achieved, as the use of liquid-free ionoelastomers mitigates limitations associated with hydrogel-based ionotronic logic devices and significantly improves device stability during operation. Second, improved device performance was realized, as surface-potential-engineered MXenes were shown to be effective for enhancing ionotronic device characteristics, thereby providing broad material design guidelines. Notably, most functional nanoscale materials inherently possess negatively charged surface potentials, and investigations focused on positively surface-charged two-dimensional nanomaterial-polymer interfaces have been rarely reported. A systematic materials-level investigation of ion diffusion in ionoelastomers coupled with positively or negatively charged MXenes, together with device-level analysis of rectification behavior in nanomaterial-incorporated ionoelastomer heterojunctions, provides insights applicable to solid-state iontronics, including ion nanochannels, ion-selective membranes, soft power generators, and ionic logic circuits.

Third, a photothermal-responsive switchable ionic diode was demonstrated. Whereas prior ionic diodes relied on modulation by ionic concentration, moisture, strain, pH variation, or temperature, an NIR-driven, noncontact, and reversible ionic diode and logic gate was realized by leveraging the high photothermal conversion efficiency of MXene. In contrast to thermally responsive circuits that rely on direct thermal contact and induce uniform heating across an entire circuit, thereby limiting selective control, the photothermal approach described herein enables noncontact and localized heating. This allows precise temperature programming of selected diodes within a circuit and enables element-specific reconfiguration. For example, selective local heating of a single diode may be optically programmed to generate four distinct current states corresponding to Boolean input combinations of (0,0), (1,0), (0,1), and (1,1), enabling multistage ionic logic operations not achievable under uniform heating conditions. In addition to NIR-responsive switchable AND to OR logic gates, switching between NAND and NOR logic operations was also realized under controlled NIR irradiation by modifying circuit configurations and altering the operational amplifier comparator connection between noninverting and inverting inputs.

Fourth, expansion of ionotronic applications was enabled. Considering the versatile applications of NIR in bioengineering and biomedical fields, the NIR-responsive ionic diode described herein may provide broad applicability in abiotic-biotic interfaces, neuroprosthetics, and neuromorphic computing. Overall, this work demonstrates a switchable logic gate based on NIR-responsive solid-state ionic junction diodes, indicating potential for multifunctional smart biomedical and sensing ionotronic systems.

### Materials

1-ethyl-3-methylimidazolium chloride ([EMIM]Cl, Sigma-Aldrich, 900771), 3-sulfopropyl acrylate potassium salt (K[SPA], Sigma-Aldrich, 251631), methoxyphenol (Sigma-Aldrich, 54050), 1-butylimidazole (Sigma-Aldrich, 348414), bis(trifluoromethane)sulfonamide lithium salt (Li[TFSI], Sigma-Aldrich, 544094), 2-hydroxyethyl acrylate (2-HEA, Sigma-Aldrich, 292818), 2,2-azobis(isobutyronitrile) (AIBN, Dawon Science, A1482), poly(ethylene glycol) (PEG, Sigma-Aldrich, 81260), triethylamine (Sigma-Aldrich, 471283), acryloyl chloride (Sigma-Aldrich, 549797), potassium carbonate (K2CO3, Sigma-Aldrich, P5833), magnesium sulfate (MgSO4, Sigma-Aldrich, 746452), ethanol, acetonitrile, dichloromethane, and deionised water were obtained from Sigma-Aldrich. Liquid metal eutectic gallium-indium (EGaIn, 75.5 wt % Ga and 24.5 wt % In, Sigma-Aldrich, 495425) and 2-bromoethyl acrylate (L12502-06) were obtained from Alfa Aesar. All other chemicals were used as received. An MXene suspension with a concentration of 10 mg mL⁻¹ was obtained from XinXi Technology Co., Ltd. (Foshan, China). VHB 4905 and VHB 4910 films were obtained from 3M and used as received.

### Fabrication of NMXene and PMXene Powder

To fabricate PMXene powder, carboxyl-modified MXene was first prepared according to a reported procedure. An MXene solution having a concentration of 1 mg mL⁻¹ and a volume of 300 mL was mechanically stirred for 40 minutes to obtain a well-dispersed suspension. Subsequently, ClCH₂COOH (5 g) was gradually added to the suspension under continuous stirring. A sodium hydroxide solution with a concentration of 6.25 mol L⁻¹ and a volume of 32 mL was then added to remove residual chemical groups. The mixture was reacted at 60 °C for 3 hours to complete the reaction. Thereafter, the mixture was washed with deionised water and dialyzed several times to improve purification, thereby yielding carboxyl-modified MXene-COOH.

Next, 2 mL of branched poly(ethylenimine) (BPEI, 86 mg mL⁻¹) was added to 40 mL of an exfoliated MXene-COOH dispersion having a concentration of 0.4 mg mL⁻¹, followed by stirring for 20 minutes. The mixture was then stirred for 2 hours at 90 °C. The resulting stable black dispersion was centrifuged at 15000 rpm and washed several times with deionised water to remove excess polymer. BPEI-functionalized, positively charged MXene was thus obtained. The PMXene powder was collected by freeze-drying. The overall synthesis process is illustrated in FIGS. 6 and 7.

Conventional Ti₃C₂Tₓ MXene contains surface functional groups such as O, OH, and F, which impart a negatively charged surface. Accordingly, NMXene powder was obtained by freeze-drying conventional MXene.

### Preparation of ES-PMXene and AT-NMXene

[EMIM][SPA] for ES and [AEBI][TFSI] for AT were synthesized following previously reported procedures. Poly(ethylene glycol) diacrylate with a molecular weight of 6 k was also synthesized according to a reported procedure. ES and AT were mixed with poly(ethylene glycol) diacrylate 6 k, 2-HEA, and an initiator (AIBN) as described previously. The prepared MXene powders were then uniformly dispersed in the ionoelastomer solutions by ultrasonication. The resulting mixtures were poured into preformed VHB film molds and thermally cured at 60 °C for 2 hours in a glovebox to form ionic elastomers. After curing, the products were washed with dichloromethane to remove unreacted monomers and subsequently dried again at 60 °C for 2 hours, as shown in FIG. 7.

### Characterizations

X-ray diffraction measurements were performed using a diffractometer (SmartLab, Rigaku) with Cu K alpha radiation over a 2θ range of 2 to 90° to evaluate crystallinity of the ionoelastomers and MXene nanosheets. Fourier transform infrared spectra were obtained using an attenuated total reflectance FTIR spectrometer (Vertex 70, Bruker). Zeta potential measurements of charged MXenes were conducted using a particle size and zeta potential analyzer (ELS-Z1000, Otsuka Electronics). Thermogravimetric analysis of ionoelastomers was carried out using a thermogravimetric analyzer (TA Instruments Q500) by increasing temperature from 25 to 700 °C at a rate of 10 °C min⁻¹ under a nitrogen atmosphere. Differential scanning calorimetry measurements were performed using a DSC instrument (TA Instruments Q200) in air by scanning temperature from −50 to 70 °C at a rate of 10 °C min⁻¹.

Morphologies and compositions of the ionoelastomers were examined using a field-emission scanning electron microscope (IT-500HR) and a transmission electron microscope (JEM-F200) equipped with energy-dispersive spectroscopy. Proton nuclear magnetic resonance spectra were used to verify structures of the ionoelastomers, and proton and fluorine nuclear magnetic resonance spectra were used to determine diffusion coefficients using a diffusion ordered spectroscopy process. Mechanical properties of the ionoelastomers were evaluated using a uniaxial tensile testing machine (Mecmeshine, 50 N load cell) at a stretching rate of 100 mm min⁻¹.

Electrochemical impedance spectra were obtained using a Biologic VPM-300 electrochemical workstation over a frequency range of 0.1 Hz to 1 MHz with an amplitude of 20 mV. Junction diode currents under various direct current biases were measured using a parameter analyzer (4200A, Keithley). Output current signals were converted to voltage signals using a resistor and measured with a data acquisition system (USB6211, National Instruments). An Arduino was programmed to activate a light-emitting diode when the output voltage exceeded a predetermined threshold.

Although the present invention has been described with reference to preferred embodiments thereof, those skilled in the art will appreciate that various modifications and changes may be made thereto without departing from the spirit and scope of the present invention as set forth in the appended claims.

What is claimed is:

1. A composite ionoelastomer material having enhanced ionic mobility, comprising: an ionoelastomer and a positively charged or negatively charged MXene included in the ionoelastomer and interacting with one of a cation and an anion contained in the ionoelastomer.

2. The composite ionoelastomer material of claim 1, wherein mobility of ions having the same charge as the MXene included in the ionoelastomer is enhanced.

3. The composite ionoelastomer material of claim 1, wherein the ionoelastomer comprises one or more materials selected from the group consisting of 1-ethyl-3-methylimidazolium (3-sulfopropyl) acrylate ([EMIM][SPA]) and 1-[2-acryloyloxyethyl]-3-butylimidazolium bis(trifluoromethane)sulfonimide ([AEBI][TFSI]).

4. The composite ionoelastomer material of claim 1, wherein the MXene comprises one or more materials selected from the group consisting of Ti₃C₂Tₓ and Ti₃C₂Tₓ surface-treated with polyethyleneimine.

5. An ionoelastomer-based diode device having enhanced ionic mobility, comprising: an n-side portion including an ionoelastomer and a negatively charged MXene interacting with cations contained in the ionoelastomer; and a p-side portion including an ionoelastomer and a positively charged MXene interacting with anions contained in the ionoelastomer, wherein the p-side portion is in contact with the n-side portion.

6. The ionoelastomer-based diode device of claim 5, further comprising: a first electrode in contact with the n-side portion; and a second electrode spaced apart from the first electrode and in contact with the p-side portion.

7. The ionoelastomer-based diode device of claim 5, wherein the ionoelastomer of the n-side portion comprises one or more materials selected from the group consisting of 1-[2-acryloyloxyethyl]-3-butylimidazolium bis(trifluoromethane)sulfonimide ([AEBI][TFSI]).

8. The ionoelastomer-based diode device of claim 5, wherein the ionoelastomer of the p-side portion comprises one or more materials selected from the group consisting of 1-ethyl-3-methylimidazolium (3-sulfopropyl) acrylate ([EMIM][SPA]).

9. The ionoelastomer-based diode device of claim 5, wherein the MXene included in the n-side portion comprises one or more materials selected from the group consisting of Ti₃C₂Tₓ.

10. The ionoelastomer-based diode device of claim 5, wherein the MXene included in the p-side portion comprises one or more materials selected from the group consisting of Ti₃C₂Tₓ surface-treated with polyethyleneimine.

11. The ionoelastomer-based diode device of claim 5, wherein the MXene included in the n-side portion or the p-side portion is present in an amount of 0.5 to 3 wt %.

12. A light-responsive gate, comprising:
a diode device including an n-side portion comprising an ionoelastomer and a negatively charged MXene interacting with cations contained in the ionoelastomer, and a p-side portion comprising an ionoelastomer and a positively charged MXene interacting with anions contained in the ionoelastomer, wherein the p-side portion is in contact with the n-side portion;
two input electrodes in contact with the p-side portion; and
an output electrode spaced apart from the input electrodes and in contact with the n-side portion,
wherein characteristics of the gate are adjustable by light.

13. The light-responsive gate of claim 12, wherein, upon irradiation with light, an electrical resistance of the diode device decreases.

14. A light-controlled device, comprising: a light-responsive gate; and a light source configured to irradiate light onto the gate, wherein the gate comprises the light-responsive gate according to claim 12.
